(19) United States
(12) Patent Application Publication
(10) Pub. No.: US 2024/0428870 A1
(43) Pub. Date: Dec. 26, 2024

(54) SEMICONDUCTOR MEMORY DEVICE AND DATA ERASING METHOD

(71) Applicant: Kioxia Corporation, Tokyo (JP)

(72) Inventors: Hayato KONNO, Yokohama Kanagawa (JP); Makoto MIAKASHI, Yokohama Kanagawa (JP)

(73) Assignee: Kioxia Corporation, Tokyo (JP)

(21) Appl. No.: 18/744,919

(22) Filed: Jun. 17, 2024

(30) Foreign Application Priority Data
Jun. 23, 2023 (JP) 2023-102954

(51) Int. Cl. G11C 16/34; G11C 16/16

(52) U.S. Cl. CPC G11C 16/3445; G11C 16/16

(57) ABSTRACT

A memory includes a plurality of planes, a controller, and a source line. The controller is configured to erase data of each memory cell in an erase target block selected in each of the planes, by executing an erase sequence that repeats a plurality of loops, each of the loops including a set of an erase operation that erases the data of each memory cell in the erase target block and an erase verification operation that checks whether the data is erased. For each erase target block, the controller is configured to detect whether there is a current leak from the source line, determine validity of the erase sequence based on a detection result, and stop execution of the erase sequence for the erase target blocks that are determined not to be valid.

### CROSS-REFERENCE TO RELATED APPLICATION

This application is based upon and claims the benefit of priority from Japanese Patent Application No. 2023-102954, filed Jun. 23, 2023, the entire contents of which are incorporated herein by reference.

### FIELD

Embodiments described herein relate generally to a semiconductor memory device and a data erasing method.

### BACKGROUND

NAND flash memory is typically considered as one kind of semiconductor memory devices.

### DESCRIPTION OF THE DRAWINGS

FIG. 1 is a block diagram illustrating a configuration example of a memory system using a semiconductor memory device according to a first embodiment;

FIG. 2 is a block diagram illustrating a configuration example of a non-volatile memory according to the first embodiment;

FIG. 3 is a diagram illustrating a configuration example of a block of a three-dimensional memory cell array according to the first embodiment;

FIG. 4 is a cross-sectional view of a block of a three-dimensional NAND memory according to the first embodiment;

FIG. 5A is a block diagram illustrating one example of voltage supply paths to each wiring of the memory cell array according to the first embodiment;

FIG. 5B is a diagram illustrating an example of the configuration of a detection circuit according to the first embodiment;

FIG. 6A is a diagram illustrating a command sequence and the operation of each plane in a comparative example;

FIG. 6B is a diagram illustrating voltage changes of each wiring in the comparative example;

FIG. 7 is a diagram illustrating a command sequence and the operation of each plane in the comparative example;

FIG. 8A is a diagram illustrating an example of a command sequence and the operation of each plane in the first embodiment;

FIG. 8B is a diagram illustrating an example of the command sequence and the operation of each plane in the first embodiment;

FIG. 8C is a diagram illustrating an example of voltage changes in each wiring of the detection circuit in the first embodiment;

FIG. 8D is a diagram illustrating an example of voltage changes of each signal line in the first embodiment;

FIG. 9A is a diagram illustrating an example of the command sequence and the operation of each plane in the first embodiment;

FIG. 9B is a diagram illustrating an example of the command sequence and the operation of each plane in the first embodiment;

FIG. 9C is a diagram illustrating an example of the command sequence and the operation of each plane in the first embodiment;

FIG. 9D is a diagram illustrating an example of the command sequence and the operation of each plane in the first embodiment;

FIG. 9E is a diagram illustrating an example of voltage changes of each wiring in the first embodiment;

FIG. 9F is a diagram illustrating an example of voltage changes of each signal line in the first embodiment;

FIG. 9G is a diagram illustrating an example of voltage changes of each signal line in the first embodiment;

FIG. 10A is a diagram illustrating an example of the command sequence and the operation of each plane in the first embodiment;

FIG. 10B is a diagram illustrating an example of the command sequence and the operation of each plane in the first embodiment;

FIG. 10C is a diagram illustrating an example of the command sequence and the operation of each plane in the first embodiment;

FIG. 11 is a block diagram illustrating another example of voltage supply paths to each wiring of the memory cell array according to the first embodiment;

FIG. 12 is a block diagram illustrating an example of voltage supply paths to each wiring of a memory cell array according to a second embodiment;

FIG. 13A is a diagram illustrating an example of a boost operation control of a pump unit during an erase operation and a detection operation according to the second embodiment;

FIG. 13B is a diagram illustrating an example of the boost operation control of the pump unit during the erase operation and the detection operation according to the second embodiment;

FIG. 13C is a diagram illustrating an example of the boost operation control of the pump unit during the erase operation and the detection operation according to the second embodiment;

FIG. 13D is a diagram illustrating an example of the boost operation control of the pump unit during the erase operation and the detection operation according to the second embodiment;

FIG. 14A is a diagram illustrating an example of a command sequence and the operation of each plane in a fourth embodiment;

FIG. 14B is a diagram illustrating an example of the command sequence and the operation of each plane in the fourth embodiment;

FIG. 14C is a diagram illustrating an example of the command sequence and the operation of each plane in the fourth embodiment;

FIG. 14D is a diagram illustrating an example of the command sequence and the operation of each plane in the fourth embodiment;

FIG. 14E is a diagram illustrating an example of the command sequence and the operation of each plane in the fourth embodiment;

FIG. 14F is a diagram illustrating an example of the command sequence and the operation of each plane in the fourth embodiment;

FIG. 14G is a diagram illustrating an example of the command sequence and the operation of each plane in the fourth embodiment;

FIG. 14H is a diagram illustrating an example of the command sequence and the operation of each plane in the fourth embodiment;

FIG. 15A is a diagram illustrating an example of threshold voltage distribution in the first embodiment; and

FIG. 15B is a diagram illustrating an example of data coding in the first embodiment.

### DETAILED DESCRIPTION

Embodiments provide a semiconductor memory device and a data erasing method that can reduce the loss of valid memory cells and use memory cells efficiently.

In general, according to one embodiment, a semiconductor memory device includes a plurality of planes, each of the plurality of planes including at least one or more blocks, each of the one or more blocks including a plurality of memory cells, a controller, and a source line electrically connected to one end of the plurality of memory cells in the plurality of planes. The controller is configured to erase data of each of the plurality of memory cells in an erase target block selected in each of the plurality of planes, by executing an erase sequence that repeats a plurality of loops, each of the loops including a set of an erase operation that erases the data of each of the plurality of memory cells in the erase target block and an erase verification operation that checks whether the data is erased. For each of the plurality of the erase target blocks, the controller is configured to detect whether there is a current leak from the source line, determine validity of the erase sequence based on a detection result, and stop execution of the erase sequence for the erase target blocks that are determined not to be valid.

Hereinafter, embodiments will be described with reference to the drawings.

### First Embodiment

### (1. Configuration)

### (1-1. Configuration of Memory System)

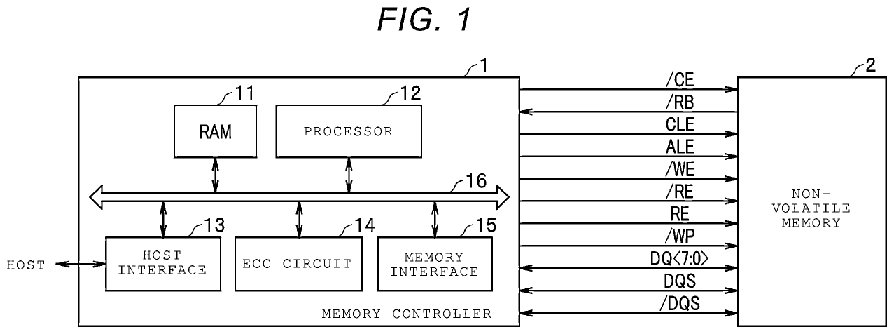

FIG. 1 is a block diagram illustrating an example of a configuration of a memory system using a semiconductor memory device according to a first embodiment. The memory system includes a memory controller 1 and a non-volatile memory 2 as a semiconductor memory device. The memory system is connectable to a host. The host is, for example, an electronic device such as a personal computer, a mobile terminal, or the like.

The non-volatile memory 2 is a memory that stores data in a non-volatile manner and includes, for example, a NAND memory (NAND flash memory). The non-volatile memory 2 is, for example, a NAND memory including memory cells capable of storing 3 bits per memory cell, that is, a NAND memory of 3 bits per cell (triple-level cell (TLC)). Note that the non-volatile memory 2 may be a NAND memory capable of storing 1 bit per cell, 2 bits per cell, or 4 bits per cell or more. The non-volatile memory 2 is typically configured with a plurality of memory chips.

The memory controller 1 controls writing of data to the non-volatile memory 2 according to a write request from the host. The memory controller 1 also controls reading of data from the non-volatile memory 2 according to a read request from the host. Between the memory controller 1 and the non-volatile memory 2, signals of a chip enable signal/CE, a ready busy signal/RB, a command latch enable signal CLE, an address latch enable signal ALE, a write enable signal/WE, read enable signals RE and/RE, a write protect signal/WP, signals DQ<7:0> that are data, and data strobe signals DOS and/DQS, are transmitted and received. The “/” added to the signal name indicates active low.

For example, the non-volatile memory 2 and the memory controller 1 are each formed as a semiconductor chip (hereinafter simply referred to as a “chip”).

The chip enable signal/CE is a signal for selecting and enabling a particular memory chip of the non-volatile memory 2. The ready busy signal/RB is a signal for indicating whether the non-volatile memory 2 is in a ready state (a state in which it is possible to accept instructions from the outside) or a busy state (a state in which it is not possible to accept instructions from the outside). The memory controller 1 can know the state of the non-volatile memory 2 by receiving the ready busy signal /RB.

The command latch enable signal CLE is a signal indicating that the signals DQ<7:0> are commands. The command latch enable signal CLE allows the command transmitted as the signal DQ to be latched to a command register in the selected memory chip of the non-volatile memory 2. The address latch enable signal ALE is a signal indicating that the signals DQ<7:0> are addresses. The address latch enable signal ALE allows the address transmitted as the signal DQ to be latched to an address register in the selected memory chip of the non-volatile memory 2. The write enable signal/WE is a signal for capturing the received signal into the non-volatile memory 2, and is asserted each time a command, an address, and data are received by the memory controller 1. The non-volatile memory 2 is instructed to capture the signals DQ<7:0> while the write enable signal/WE is at the “L (low)” level.

The read enable signals RE and/RE are signals for the memory controller 1 to read data from the non-volatile memory 2. For example, the signals are used to control the operation timing of the non-volatile memory 2 when outputting the signals DQ<7:0>. The write protect signal/WP is a signal for instructing the non-volatile memory 2 to prohibit data writing and erasing. The signals DQ<7:0> are data transmitted and received between the non-volatile memory 2 and the memory controller 1, and includes a command, an address, and data. The data strobe signals DOS and/DOS are signals for controlling the timing of input and output of the signals DQ<7:0>.

The memory controller 1 includes a random access memory (RAM) 11, a processor 12, a host interface 13, an error check and correct (ECC) circuit 14, and a memory interface 15. The RAM 11, the processor 12, the host interface 13, the ECC circuit 14, and the memory interface 15 are connected to each other by an internal bus 16.

The host interface 13 receives requests such as write requests and read requests, user data (write data), and the like from the host. The host interface 13 transmits user data read from the non-volatile memory 2, a response from the processor 12, and the like to the host.

The memory interface 15 controls a process for writing user data or the like to the non-volatile memory 2 and a process for reading user data or the like from the non-volatile memory 2 based on instructions of the processor 12.

The RAM 11 temporarily stores user data received from the host until the user data is stored in the non-volatile memory 2, or temporarily stores data read from the non-volatile memory 2 until the read data is transmitted to the host. The RAM 11 is, for example, a general-purpose memory such as a static random access memory (SRAM) or a dynamic random access memory (DRAM).

The processor 12 collectively controls the memory controller 1. The processor 12 is, for example, a central processing unit (CPU), a micro processing unit (MPU), or the like. The processor 12 performs control according to a request when a request is received from the host via the host interface 13. For example, the processor 12 instructs the memory interface 15 to write user data to the non-volatile memory 2 according to a request from the host. The processor 12 instructs the memory interface 15 to read user data from the non-volatile memory 2 according to a request from the host.

The processor 12 determines a storage area (memory area) on the non-volatile memory 2 for the user data stored in the RAM 11. The user data received from the host is temporarily stored in the RAM 11 via the internal bus 16. The processor 12 performs a determination of the memory area on data in a unit of pages (page data), that is a unit of writing. The user data temporarily stored in the RAM 11 is generally encoded by the ECC circuit 14 and stored in the determined memory area of the non-volatile memory 2 as unit data. A physical address is assigned to the memory area of the non-volatile memory 2. The processor 12 manages a memory area to which unit data is to be written using a physical address. The processor 12 specifies a determined memory area (physical address) and instructs the memory interface 15 to write user data to the non-volatile memory 2. The processor 12 manages the correspondence between a logical address (logical address managed by the host) and the physical address of the user data. When a read request including a logical address is received from the host, the processor 12 identifies a physical address corresponding to the logical address and instructs the memory interface 15 to read the user data by specifying the physical address.

The ECC circuit 14 encodes the user data stored in the RAM 11 to generate the unit data. The ECC circuit 14 decodes the encoded unit data read from the non-volatile memory 2. Although the present embodiment illustrates a configuration in which encoding is performed as a configuration example, encoding is not necessarily required. The memory controller 1 may store page data in the non-volatile memory 2 without encoding.

FIG. 1 illustrates a configuration example in which the memory controller 1 includes the ECC circuit 14 and the memory interface 15, respectively. However, the ECC circuit 14 may be built into the memory interface 15. The ECC circuit 14 may also be built into the non-volatile memory 2.

When a write request is received from the host, the memory system operates as follows. The processor 12 causes the RAM 11 to temporarily store data to be written. The processor 12 reads out the data stored in the RAM 11 and inputs the read data to the ECC circuit 14. The ECC circuit 14 encodes the input data and inputs the encoded data to the memory interface 15. The memory interface 15 writes the encoded data to the non-volatile memory 2.

When a read request is received from the host, the memory system operates as follows. The memory interface 15 inputs the encoded data read from the non-volatile memory 2 to the ECC circuit 14. The ECC circuit 14 decodes the encoded data and stores the decoded data in the RAM 11. The processor 12 transmits data stored in the RAM 11 to the host via the host interface 13.

### (1-2. Configuration of Non-Volatile Memory)

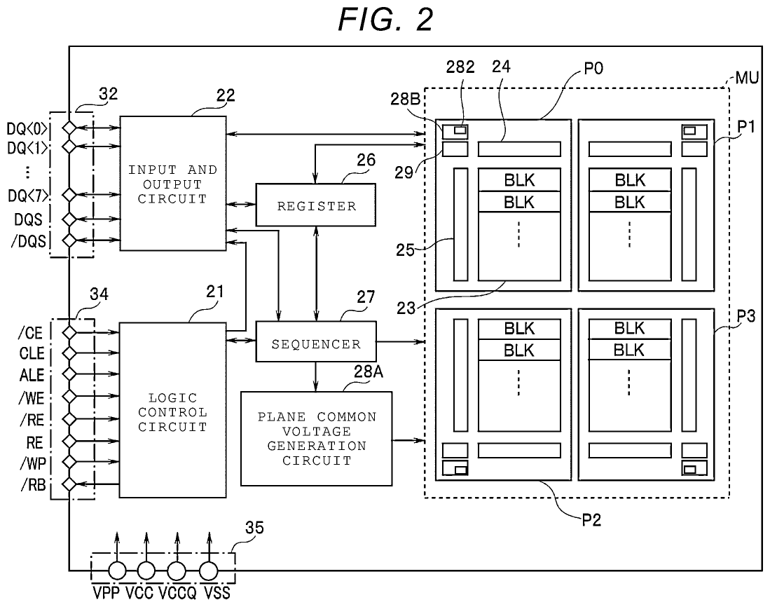

FIG. 2 is a block diagram illustrating a configuration example of a non-volatile memory according to the first embodiment. The non-volatile memory 2 includes a logic control circuit 21, an input and output circuit 22, a memory cell unit MU, a register 26, a sequencer 27, a plane common voltage generation circuit 28A, an input and output pad group 32, a logic control pad group 34, and a power input terminal group 35.

The memory cell unit MU incudes a plurality of planes P0 to P3. The planes P0 to P3 are units capable of independently executing read operations, write operations, and erase operations. Although FIG. 2 illustrates, by way of example, a case where four planes are disposed in the non-volatile memory 2, the number of planes may be equal to or less than three, or may be equal to or larger than five. The planes P0 to P3 include a memory cell array (memory cell portion) 23, a sense amplifier 24, a row decoder 25, a driver set 29, and a plane voltage generation circuit 28B.

The memory cell array 23 includes a plurality of blocks BLK. Each of the plurality of blocks BLK includes a plurality of memory cell transistors (memory cells). A plurality of bit lines, a plurality of word lines, a source line, and the like are arranged in the memory cell array 23 to control voltage applied to the memory cell transistor. The specific configuration of the block BLK will be described later.

The input and output pad group 32 includes a plurality of pads (terminals) corresponding to the signals DQ<7:0> and the data strobe signals DQS and/DQS to transmit and receive each signal including data to and from the memory controller 1.

The logic control pad group 34 includes a plurality of pads (terminals) corresponding to the chip enable signal/CE, the command latch enable signal CLE, the address latch enable signal ALE, the write enable signal/WE, the read enable signals RE and/RE, and the write protect signal/WP to transmit and receive each signal to and from the memory controller 1.

The power input terminal group 35 includes a plurality of terminals that input power supply voltages VCC, VCCQ, and VPP and a ground voltage VSS to supply various operating power to the non-volatile memory 2 from the outside. The power supply voltage VCC is a circuit power supply voltage generally given from the outside as an operating power, and for example, a voltage of about 3.3 V is input. For example, a voltage of 1.2 V is input as the power supply voltage VCCQ. The power supply voltage VCCQ is used when transmitting and receiving signals between the memory controller 1 and the non-volatile memory 2.

The power supply voltage VPP is a power supply voltage that is higher than the power supply voltage VCC, and for example, a voltage of 12 V is input. When writing data to the memory cell array 23 or erasing data, a high voltage of about 20 V is required. Here, it is possible to generate a desired voltage at a high speed and with a low power consumption by boosting the power supply voltage VPP of about 12 V rather than boosting the power supply voltage VCC of about 3.3 V. The power supply voltage VPP is, for example, a power supply that is additionally and optionally supplied depending on a use environment.

The logic control circuit 21 and the input and output circuit 22 are connected to the memory controller 1 via a NAND bus. The input and output circuit 22 transmits and receives the signals DQ<7:0> (for example, DQ0 to DQ7) to and from the memory controller 1 via the NAND bus.

The logic control circuit 21 receives external control signals (for example, the chip enable signal/CE, the command latch enable signal CLE, the address latch enable signal ALE, the write enable signal/WE, the read enable signals RE and/RE, and the write protect signal/WP) from the memory controller 1 via the NAND bus. The logic control circuit 21 transmits the ready busy signal/RB to the memory controller 1 via the NAND bus.

The input and output circuit 22 transmits and receives the signals DQ<7:0> and the data strobe signals DOS and/DQS to and from the memory controller 1. The input and output circuit 22 transfers the commands and addresses in the signals DQ<7:0> to the register 26. The input and output circuit 22 transmits and receives write data and read data to and from the sense amplifier 24 of each of the planes P0 to P3.

The register 26 includes a command register, an address register, a status register, and the like. The command register temporarily stores commands. The address register temporarily stores addresses. The status register temporarily stores data necessary for the operation of the non-volatile memory 2. The register 26 is configured with, for example, an SRAM.

The sequencer 27 as a control unit (or controller) receives a command from the register 26 and controls the non-volatile memory 2 according to the sequence based on the command.

The plane common voltage generation circuit 28A receives a power supply voltage from the outside of the non-volatile memory 2 and uses the power supply voltage to generate a voltage common to the plurality of planes. The plane common voltage generation circuit 28A generates, for example, a voltage required for an erase operation (VERA). The plane common voltage generation circuit 28A supplies the generated voltage to the memory cell array 23 in each of the planes P0 to P3.

The plane voltage generation circuit 28B receives a power supply voltage from the outside of the non-volatile memory 2 and uses the power supply voltage to generate a plurality of voltages necessary for write operations, read operations, and erase operations. The plane voltage generation circuit 28B supplies the generated voltage to the memory cell array 23, the sense amplifier 24, the row decoder 25, the driver set 29, and the like, disposed on the same planes P0 to P3 as itself. The plane voltage generation circuit 28B also includes a detection circuit 282. One detection circuit 282 of the present embodiment is provided for each of the planes P0 to P3, and can detect a leakage current in each of the planes P0 to P3.

The driver set 29 receives various voltages from the plane voltage generation circuit 28B and selects a voltage suitable for operation and transfers the selected voltage to the row decoder 25 and the sense amplifier 24.

The row decoder 25 receives a row address from the register 26 and decodes the row address. The row decoder 25 performs a word line selection operation based on the decoded row address. Then, the row decoder 25 transfers the plurality of voltages required for the write operation, the read operation, and the erase operation to the selected block.

The sense amplifier 24 receives a column address from the register 26 and decodes the column address. The sense amplifier 24 includes a sense amplifier unit group and a data register. The sense amplifier unit group is connected to each bit line and selects any one of the bit lines based on the decoded column address. The sense amplifier unit group detects and amplifies data read from the memory cell transistor to the bit line when reading data. The sense amplifier unit group transfers write data to the bit line when writing data.

When reading data, the data register temporarily stores the data detected by the sense amplifier unit group and serially transfers the detected data to the input and output circuit 22. When writing data, the data register temporarily stores data serially transferred from the input and output circuit 22 and transfers the data to the sense amplifier unit group. The data register is configured with an SRAM and the like.

### (1-3. Block Configuration of Memory Cell Array)

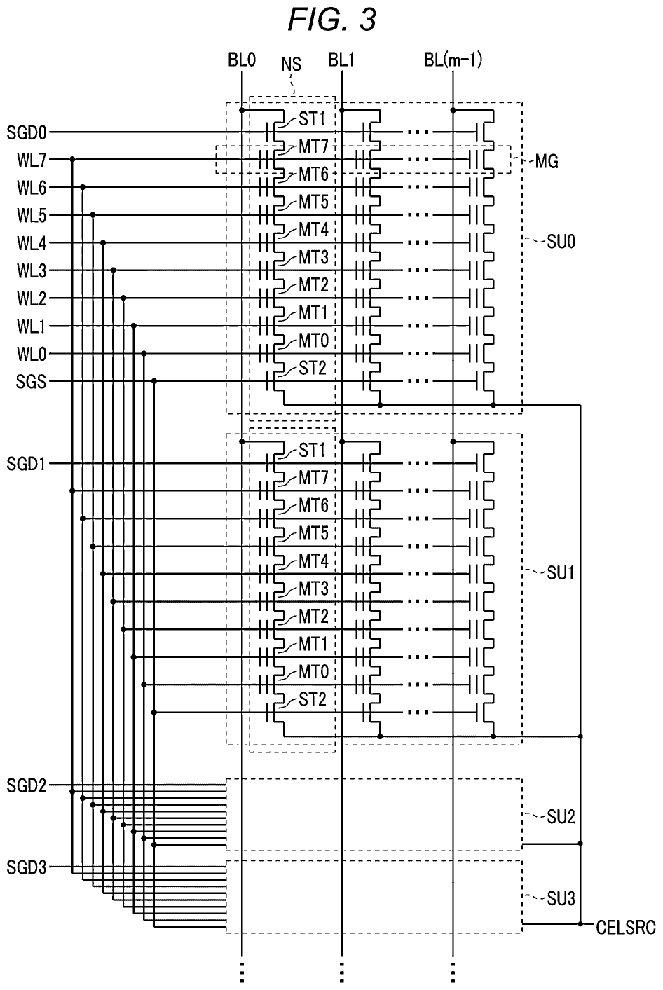

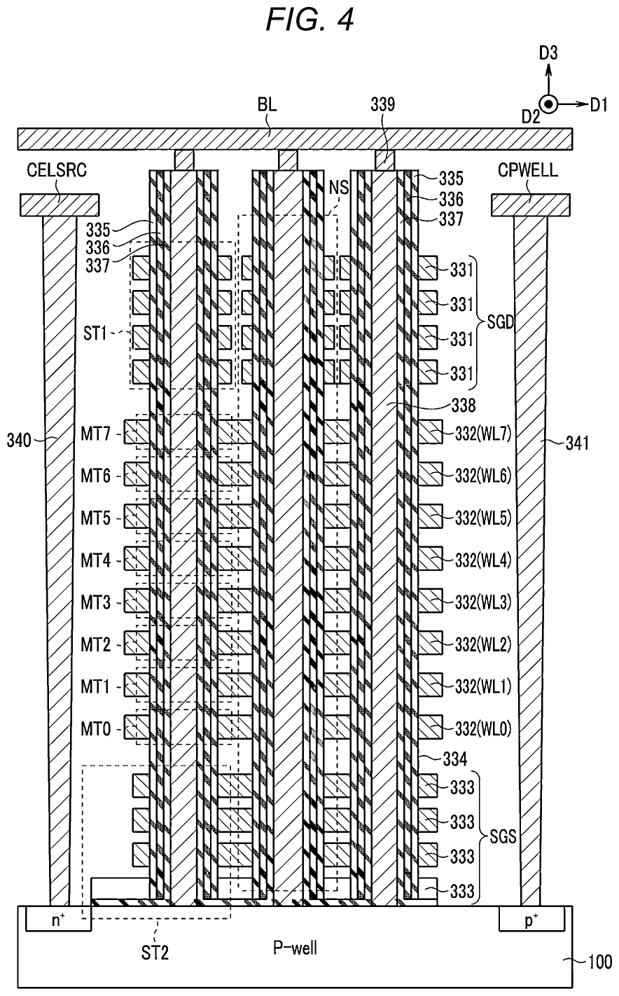

FIG. 3 is a diagram illustrating a configuration example of a block of a three-dimensional memory cell array according to the first embodiment. FIG. 3 illustrates one block BLK among a plurality of blocks in the memory cell array 23. FIG. 4 is a cross-sectional view of a block of a three-dimensional NAND memory according to the first embodiment. The other blocks of the memory cell array also have a circuit configuration similar to that of FIG. 3 and a cross-sectional structure similar to that of FIG. 4.

As illustrated in FIG. 3, the block BLK includes, for example, four string units (SU0 to SU3). Each string unit SU includes a plurality of NAND strings NS. Here, each of the NAND strings NS includes eight memory cell transistors MT (MT0 to MT7) and select gate transistors ST1 and ST2. The memory cell transistor MT includes a gate and a charge storage layer, and stores data in a non-volatile manner. Although the number of memory cell transistors MT in the NAND string NS is set as eight for convenience, the number may be larger than eight.

Although the select gate transistors ST1 and ST2 are shown as one transistor on the electrical circuit, the structure may be the same as the memory cell transistor. A plurality of select gate transistors may be used, for example, as each of the select gate transistors ST1 and ST2. A dummy cell transistor may be provided between the memory cell transistor MT and the select gate transistors ST1 and ST2.

The memory cell transistor MT is arranged to be connected in series between the select gate transistors ST1 and ST2. The memory cell transistor MT7 on one end is connected to the select gate transistor ST1, and the memory cell transistor MT0 on the other end is connected to the select gate transistor ST2.

The gates of the select gate transistors ST1 of each of the string units SU0 to SU3 are respectively connected to select gate lines SGD0 to SGD3 (hereinafter referred to as a select gate line SGD when it is not necessary to distinguish between SGD0 to SGD3). On the other hand, the gates of the select gate transistors ST2 are commonly connected to the same select gate line SGS between the plurality of string units SU in the same block BLK. The gates of the memory cell transistors MT0 to MT7 in the same block BLK are commonly connected to the word lines WL0 to WL7, respectively. In other words, the word lines WL0 to WL7 and the select gate line SGS are commonly connected between the plurality of string units SU0 to SU3 in the same block BLK, while the select gate line SGD is independent for each of the string units SU0 to SU3 even in the same block BLK.

The word lines WL0 to WL7 are connected to the gates of the memory cell transistors MT0 to MT7 that configure the NAND string NS, respectively. The gate of the memory cell transistor MTi in the same row in the block BLK is connected to the same word line WLi. In the following description, the NAND string NS may be simply referred to as a “string”.

Each NAND string NS is connected to a corresponding bit line. Accordingly, each memory cell transistor MT is connected to the bit line via a select gate transistor ST or other memory cell transistors MT in the NAND string NS. Data of the memory cell transistor MT in the same block BLK is erased all at once. On the other hand, reading and writing data is performed in units of memory cell groups MG (or in units of pages). In the present specification, a plurality of memory cell transistors MT connected to one word line WLi (i is an integer of 0 or more) and belonging to one string unit SU are defined as a memory cell group MG. During the read operation and the write operation, one word line WLi and one select gate line SGD are selected according to the physical address, and the memory cell group MG is selected.

In FIG. 4, a D1 direction corresponds to an extending direction of the bit line BL, a D2 direction corresponds to an extending direction of the word line WL and the select gate lines SGD and SGS, and a D3 direction corresponds to a stacking direction of the word line WL and the select gate lines SGD and SGS. The D1 direction is parallel to a surface of a semiconductor substrate 100, the D2 direction is parallel to the surface of the semiconductor substrate 100 and orthogonal to the D1 direction, and the D3 direction is perpendicular to the surface of the semiconductor substrate 100 and orthogonal to the D1 direction and the D2 direction.

As illustrated in FIG. 4, a plurality of NAND strings NS are formed on a p-type well region (P-well). In other words, a plurality of wiring layers 333 serving as the select gate line SGS, a plurality of wiring layers 332 serving as the word line WLi, and a plurality of wiring layers 331 serving as the select gate line SGD are stacked on the p-type well region.

Then, a memory hole 334 is formed that reaches the p-type well region while passing through the wiring layers 333, 332, and 331. On the side surface of the memory hole 334, a block insulating film 335, a charge storage layer 336, and a gate insulating film 337 are sequentially formed, and a conductor pillar 338 is further embedded in the memory hole 334. The conductor pillar 338 is made of, for example, polysilicon, and functions as a region in which a channel is formed during operation of the memory cell transistor MT and the select gate transistors ST1 and ST2 in the NAND string NS.

In each NAND string NS, the select gate transistor ST2, a plurality of memory cell transistors MT, and the select gate transistor ST1 are formed on the p-type well region. On the upper side of the conductor pillar 338, a wiring layer is formed that functions as a bit line BL. On the upper side of the conductor pillar 338, a contact plug 339 is formed to connect the conductor pillar 338 and the bit line BL.

An n+ type impurity diffusion layer and a p+ type impurity diffusion layer are formed in the surface of the p-type well region. On the n+ type impurity diffusion layer, a contact plug 340 is formed, and on the contact plug 340, a wiring layer serving as a source line CELSRC is formed. A contact plug 341 is formed on the p+ type impurity diffusion layer, and the wiring layer serving as a well wire CPWELL is formed on the contact plug 341.

A plurality of the configuration illustrated in FIG. 4 above are arranged in the depth direction (D2 direction) of the paper in FIG. 4, and one string unit SU is formed by the collection of the plurality of NAND strings aligned in a row in the depth direction.

### (1-4. Voltage Supply to Each Wiring of Memory Cell Array)

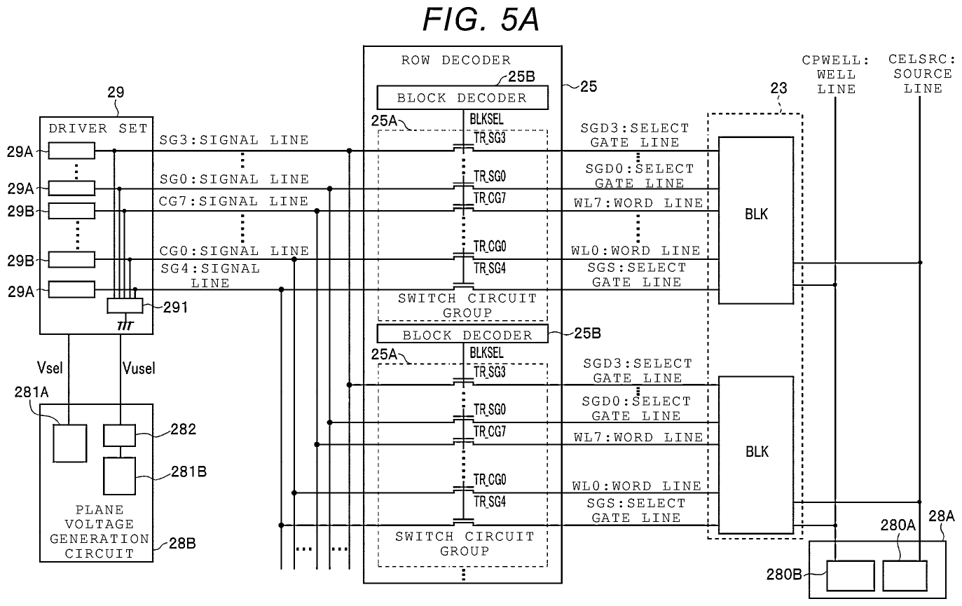

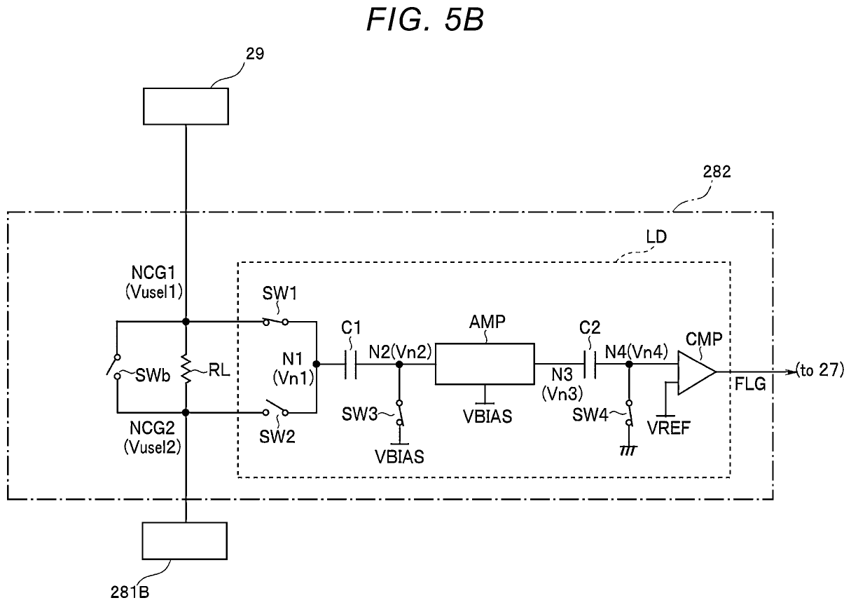

FIG. 5A is a block diagram illustrating voltage supply paths to each wiring of the memory cell array. The driver set 29 includes a plurality of SG drivers 29A that respectively supply voltage to signal lines SG0 to SG4 and a plurality of CG drivers 29B that respectively supply voltage to signal lines CG0 to CG7. The signal lines SG0 to SG4, and CG0 to CG7 are connected to wirings of each block BLK via the row decoder 25. That is, the signal lines SG0 to SG3 function as global drain-side select gate lines and are connected to the select gate lines SGD0 to SGD3 as local select gate lines in each block BLK via the row decoder 25. The signal lines CG0 to CG7 function as global word lines and are connected to the word lines WL0 to WL7 as local word lines in each block BLK via the row decoder 25. The signal line SG4 functions as a global source-side select gate line and is connected to the select gate line SGS as a local select gate line in each block BLK via the row decoder 25.

The SG driver (select gate line driver) 29A and the CG driver (word line driver) 29B respectively supply various voltages generated by the plane voltage generation circuit 28B to the corresponding signal lines SG0 to SG4 and the signal lines CG0 to CG7.

For example, during the write operation, each CG driver 29B supplies either a voltage VPGM or a voltage VPASS according to the corresponding signal line CG and the word line WL depending on the target (row address) of the operation in the write operation. The CG driver 29B connected to the signal line CG corresponding to the word line WLn, that is the target of the write operation, supplies the voltage VPGM. The CG driver 29B connected to the signal lines CGn±1, CGn±2, and the like corresponding to the other word lines WLn±1, WLn±2, and the like supplies the voltage VPASS. The voltage VPASS is a voltage that sets the memory cell transistor MT to be turned on. The voltage VPGM is a voltage for injecting electrons into the charge storage layer 336, and is VPGM>VPASS.

The driver set 29 also includes a signal line equalization circuit 291. The signal line equalization circuit 291 is a circuit that discharges the connected wiring. The signal lines SG0 to SG4, and CG0 to CG7 are connected to the signal line equalization circuit 291.

The plane voltage generation circuit 28B generates various voltages and transfers generated voltages to the driver set 29. The plane voltage generation circuit 28B includes a plurality of pump units 281A and 281B, and the detection circuit 282. Although FIG. 5A illustrates a case where the plane voltage generation circuit 28B includes two pump units 281A and 281B, the number of the pump units may be three or more. The pump unit 281A outputs, for example, a voltage Vsel to be transferred to the selected word line WL to the driver set 29. The voltage Vsel is, for example, the voltage VPGM or the like.

The pump unit 281B outputs, for example, a voltage Vusel to be transferred to the non-selected word line WL to the driver set 29. The voltage Vusel is, for example, the voltage VPASS, a voltage VREAD, a voltage VCGRV, or the like. The voltage VREAD is a voltage that causes the memory cell transistor MT to be turned on when reading, regardless of the charge accumulated in the charge storage layer 336 of the memory cell transistor MT (data stored by the memory cell transistor MT). The voltage VCGRV is a read reference voltage, and is VREAD>VCGRV.

The detection circuit 282 is a circuit that detects a current flowing in the signal lines CG0 to CG7. The detection circuit 282 is used as a circuit to detect a leakage current between the source line CELSRC and the word line WL of the selected block BLK during the erase operation. The detection circuit 282 is connected to the pump unit 281B. FIG. 5B is a diagram illustrating an example of a configuration of a detection circuit according to the first embodiment. The detection circuit 282 includes, for example, a switch SWb, a resistor RL, and a leak detection unit LD. An output end of the pump unit 281B is connected to a node NCG2. A first end of the switch SWb is connected to the node NCG2, and a second end of the switch SWb is connected to a node NCG1. One end of the resistor RL is connected to the node NCG2, and the other end of the resistor RL is connected to the node NCG1. The switch SWb is, for example, a two-terminal switch element that enables signal transmission between the first end and the second end while the switch SWb is turned on.

The leak detection unit LD is connected to the nodes NCG1 and NCG2. The leak detection unit LD detects the current flowing in the signal lines CG0 to CG7 based on a voltage Vusel1 of the node NCG1 and a voltage Vuse12 of the node NCG2. The leak detection unit LD can perform either a process of detecting the current flowing into the signal lines CG0 to CG7 or a process of detecting the current flowing out of the signal lines CG0 to CG7 as the leak detection process. Here, since the leak detection unit LD is used to detect the current flowing into the word line WL from the source line CELSRC, the leak detection unit LD performs the process of detecting the current flowing into the signal lines CG0 to CG7.

For example, during the leak detection process by the leak detection unit LD, the switch SWb is turned off, but otherwise, the switch SWb is turned on. The switch SWb that is turned on transmits a voltage output from the pump unit 281B to the node NCG2 to which the first end is connected to the node NCG1 to which the second end is connected. Thereby, the voltage output by the pump unit 281B can be transferred to the driver set 29.

The leak detection unit LD includes, for example, switches SW1, SW2, SW3, and SW4, capacitive elements C1 and C2, an amplifier circuit AMP, and a comparator CMP. First, the connection relationship thereof in the leak detection unit LD will be described. A first end of the switch SW1 is connected to the node NCG1, and a second end of the switch SW1 is connected to a node N1. The connection between the leak detection unit LD and the node NCG1 is achieved by the connection between the first end of the switch SW1 and the node NCG1. A first end of the switch SW2 is connected to the node NCG2, and a second end of the switch SW2 is connected to the node N1. The connection between the leak detection unit LD and the node NCG2 is achieved by the connection between the first end of the switch SW2 and the node NCG2.

A first electrode of the capacitive element C1 is connected to the node N1, and a second electrode of the capacitive element C1 is connected to a node N2. A first end of the switch SW3 is connected to the node N2, and a voltage VBIAS is applied to the second end of the switch SW3. The voltage VBIAS is, for example, a certain reference voltage that is substantially constant. An input end of the amplifier circuit AMP is connected to the node N2, and the voltage VBIAS is applied to a reference voltage end of the amplifier circuit AMP. An output end of the amplifier circuit AMP is connected to a node N3. A first electrode of the capacitive element C2 is connected to the node N3, and a second electrode of the capacitive element C2 is connected to a node N4.

A first end of the switch SW4 is connected to the node N4, and a second end of the switch SW4 is grounded, for example. Hereinafter, description is made assuming that the second end of the switch SW4 is grounded and a voltage of 0 V is applied to the second electrode. A first input end of the comparator CMP is connected to the node N4, and a voltage VREF is applied to a second input end of the comparator CMP. The voltage VREF is, for example, a certain reference voltage that is substantially constant. The voltage VREF is, for example, lower than 0 V.

Next, each component in the leak detection unit LD will be further described. For example, while the switch SW1 is turned on and the switch SW2 is turned off, the switch SW1 transmits the voltage Vusel1 of the node NCG1 to the node N1. On the other hand, for example, while the switch SW1 is turned off and the switch SW2 is turned on, the switch SW2 transmits the voltage Vusel2 of the node NCG2 to the node N1. As such, the switch SW1 and the switch SW2 can selectively transfer one of the voltage Vusel1 and the voltage Vuse12 to the node N1. When there is a leakage current on the word line WL, while the switch SWb is turned off and at least one of the switch SW1 and the switch SW2 is turned off, the leakage current flows between the node NCG1 and the node NCG2 via the resistor RL. The switch SW1 and the switch SW2 may change the voltage Vn1 of the node N1 between the voltage Vusel1 and the voltage Vusel2 by sequentially transferring the voltage Vusel1 and the voltage Vuse12 that differ from each other as such to the node N1. The switch SW1 and the switch SW2 change the voltage Vn1 from, for example, the higher of the voltage Vusel1 and the voltage Vusel2 to the lower of the voltage Vusel1 and the voltage Vusel2.

While the switch SW3 is turned on, the switch SW3 transmits the voltage VBIAS applied to the second end to the node N2 connected to the first end. As such, the switch SW3 can fix the voltage of the node N2 to the voltage VBIAS. On the other hand, while the switch SW3 is turned off, the capacitive element C1 maintains a potential difference between the first electrode and the second electrode of the capacitive element C1 when the switch SW3 is turned off. For example, when the voltage Vn1 changes while the switch SW3 is turned off, the capacitive element C1 maintains the potential difference between the first electrode and the second electrode by changing the voltage Vn2 by substantially the same amount as the change in the voltage Vn1. Accordingly, the capacitive element C1 can transmit the change in the voltage Vn1 to the node N2 as the change in the voltage Vn2.

The amplifier circuit AMP amplifies the voltage Vn2 at the node N2 connected to the input end of the amplifier circuit AMP based on the voltage VBIAS applied to the reference voltage end of the amplifier circuit AMP, and outputs the signal resulting from the amplification to the node N3 connected to the output end of the amplifier circuit AMP. Hereinafter, it will be described assuming that the magnification of the amplification is 10 times, but the magnification of the amplification is not necessarily limited thereto.

When the voltage Vn2 changes, the amplifier circuit AMP outputs the signal resulting from the amplification of the voltage Vn2 based on the voltage VBIAS on the node N3, and thus, the voltage Vn3 on the node N3 changes by substantially the same amount as the change in the voltage Vn2 multiplied by 10. As such, the amplifier circuit AMP amplifies the change in the voltage Vn2 and transmits the change to the node N3 as a change in the voltage Vn3.

While the switch SW4 is turned on, the switch SW4 transmits 0 V applied to the second end to the node N4 connected to the first end. As such, the switch SW4 can fix the voltage Vn4 of the node N4 to a voltage of 0 V. On the other hand, while the switch SW4 is turned off, the capacitive element C2 maintains a potential difference between the first electrode and the second electrode of the capacitive element C2 when the switch SW4 is turned off. For example, when the voltage Vn3 changes while the switch SW4 is turned off, the capacitive element C2 maintains the potential difference between the first electrode and the second electrode, and thus, the voltage Vn4 changes by substantially the same amount as the change in the voltage Vn3. As such, the capacitive element C2 can transmit the change in the voltage Vn3 to the node N4 as a change in the voltage Vn4.

The comparator CMP outputs the signal resulting from the comparison of the voltage of the node N4 connected to the first input end with the voltage VREF applied to the second input end. The signal is a signal FLG. The level of the signal FLG differs depending on whether the level of the voltage Vn4 is below the voltage VREF. The change in the level of the signal FLG may mean that a leakage current is detected.

The circuit configuration of the detection circuit 282 is not limited to the configuration described above. For example, the leak detection unit LD may have another configuration that can detect the leakage current based on the change in the voltage Vn1 described above. The row decoder 25 includes a plurality of switch circuit groups 25A corresponding to each block BLK and a plurality of block decoders 25B corresponding to each of the plurality of switch circuit groups 25A. Each switch circuit group 25A includes a plurality of transistors TR_SG0 to TR SG3 that respectively connect the signal lines SG0 to SG3 and the select gate lines SGD0 to SGD3, a plurality of transistors TR_CG0 to TR_CG7 that respectively connect the signal lines CG0 to CG7 and the word lines WL0 to WL7, and a transistor TR SG4 that connects the signal line SG4 and the select gate line SGS. Each of the transistors TR_SG0 to TR SG4 and the transistors TR_CG0 to TR_CG7 is a high breakdown voltage transistor.

When the row address specifies each block decoder 25B, the specified block decoder 25B supplies a block selection signal BLKSEL to the gates of the transistors TR_SG0 to TR SG4 and the transistors TR_CG0 to TR_CG7. As a result, in the switch circuit group 25A where the block selection signal BLKSEL is supplied from the block decoder 25B specified by the row address, the transistor TR_SG0 to TR SG4 and the transistor TR_CG0 to TR_CG7 are turned on and are electrically connected. Therefore, the voltage supplied to the signal lines SG0 to SG4 and the signal lines CG0 to CG7 from the plane voltage generation circuit 28B is supplied to the select gate lines SGD0 to SGD3 and SGS, and the word lines WL0 to WL7 in the block BLK to be operated.

The plane common voltage generation circuit 28A includes a plurality of pump units 280A and 280B. The pump unit 280A generates a voltage to be supplied to the well line CPWELL for all of the planes P0 to P3 in the memory unit MU. The well line CPWELL is commonly connected to each block BLK. The pump unit 280B generates a voltage VERA, a voltage VCELSRC, and the like to be supplied to the source line CELSRC for all of the planes P0 to P3 in the memory unit MU. The voltage VERA is an erase voltage that can extract the charge accumulated in the charge storage layer 336 during the data erase operation, for example, a high voltage of 20 V or more. The voltage VCELSRC is the voltage applied to the source line CELSRC when reading data. The source line CELSRC is also commonly connected to each block BLK.

### (2. Operation)

Next, a data erase operation (hereinafter referred to as an erase operation), that is a characteristic operation in the present embodiment, will be described.

### (2-0. Threshold Voltage Distribution of Memory Cell Transistor)

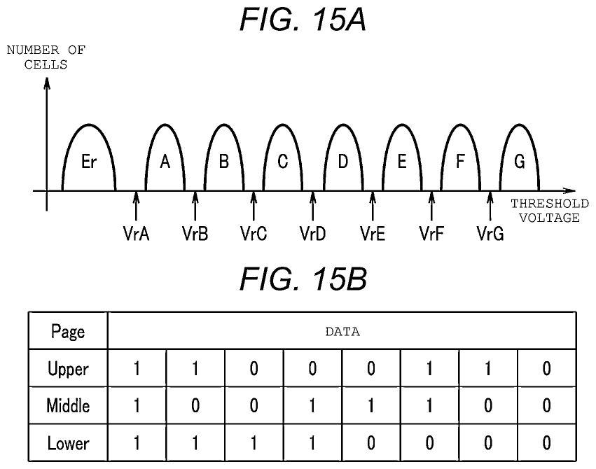

Prior to the description of the data erase operation, the threshold voltage distribution of the memory cell transistor will be described. FIG. 15A is a diagram illustrating an example of a threshold voltage distribution according to the first embodiment. FIG. 15A illustrates an example of the threshold voltage distribution of the non-volatile memory 2 of 3 bit per cell. In the non-volatile memory 2, information is stored by the amount of charge stored in the charge storage layer of the memory cell. Each memory cell has a threshold voltage depending on the amount of charge. The plurality of data values stored in the memory cell are made to correspond to the plurality of regions of the threshold voltage (the threshold voltage distribution region), respectively.

Eight distributions (mountain shape) described as Er, A, B, C, D, E, F, and G in FIG. 15A indicate eight threshold voltage distribution regions. As such, each memory cell has a threshold voltage distribution divided by seven boundaries. The horizontal axis of FIG. 15A represents the threshold voltage, and the vertical axis represents the distribution of the number of memory cells (number of cells).

In the present embodiment, a region in which the threshold voltage is less than or equal to VrA is called a region Er (Er state), a region in which the threshold voltage is greater than VrA and less than or equal to VrB is called a region A, a region in which the threshold voltage is greater than VrB and less than or equal to VrC is called a region B, and a region in which the threshold voltage is greater than VrC and less than or equal to VrD is called a region C. In the present embodiment, a region in which the threshold voltage is greater than VrD and less than or equal to VrE is called a region D, a region in which the threshold voltage is greater than VrE and less than or equal to VrF is called a region E, a region in which the threshold voltage is greater than or equal to VrF and less than or equal to VrG is called a region F, and a region in which the threshold voltage is greater than VrG is called a region G.

The threshold voltage distributions corresponding to the regions Er, A, B, C, D, E, F, and G are called distributions Er, A, B, C, D, E, F, and G (first to eighth distributions), respectively. VrA to VrG are threshold voltages that become the boundaries of each region.

In the non-volatile memory 2, the plurality of data values are made to correspond to the plurality of threshold voltage distribution regions of the memory cell, respectively. The correspondence is called data coding. The data coding is predetermined, and when writing data (programming), charge is injected into the memory cell so that the memory cell is within the threshold voltage distribution region corresponding to the data value stored according to the data coding. Then, when reading, the read voltage is applied to the memory cell, and the data is determined by whether the threshold voltage of the memory cell is lower or higher than the read voltage.

FIG. 15B is a diagram illustrating an example of data coding according to the first embodiment. The three bits of the eight threshold voltage distribution regions illustrated in FIG. 15A are made to respectively correspond to eight data values, for example, as illustrated in FIG. 15B. The relationship between the threshold voltage and the data values of bits corresponding to Upper, Middle, and Lower pages is as indicated below.
The memory cell with the threshold voltage in the Er region is storing “111”.
The memory cell with the threshold voltage in the A region is storing “101”.
The memory cell with the threshold voltage in the B region is storing “001”.
The memory cell with the threshold voltage in the C region is storing “011”.
The memory cell with the threshold voltage in the D region is storing “010”.
The memory cell with the threshold voltage in the E region is storing “110”.
The memory cell with the threshold voltage in the F region is storing “100”.
The memory cell with the threshold voltage in the G region is storing “000”.

As such, the state of the 3-bit data of each memory cell can be represented for each region of the threshold voltage. When the memory cell is not written (the state of “erase”), the threshold voltage of the memory cell is in the Er region. In the code shown here, only 1 bit of data changes between any two adjacent states, such as storing the data “111” in the Er (erase) state and storing the data “101” in the A state. As such, the coding shown in FIG. 15B is a gray code in which only 1 bit of data changes between any two adjacent regions.

Although in FIG. 15A, a case where the eight levels are distributed discretely is described as an example, the case is an ideal state immediately after the data is written, for example. Thus, in reality, adjacent levels may overlap. For example, after the data is written, an upper end of the distribution Er and a lower end of the distribution A may overlap due to a disturbance or the like. Then, the data is corrected using, for example, ECC technology.

### (2-1. Concept of Erase Operation)

The erase operation is an operation that causes the charge accumulated in the charge storage layer 336 of each memory transistor MT in the selected block BLK to be discharged to set the threshold voltage of the memory cell transistors MT to an erase level (Er state). The erase operation roughly includes an erase operation (Erase) and an erase verification operation (Evfy).

The erase operation is an operation that discharges the charge from the charge storage layer 336. A high voltage (voltage VERA) is applied to the source line CELSRC, and the potential difference with the select gate line SGS causes a hole (main hole) to be generated in the memory hole 334 by gate-induced drain leakage (GIDL). The charge accumulated in the charge storage layer 336 recouples with the hole, thereby returning the threshold voltage of the memory cell transistor MT to the Er state.

The erase verification operation is a read operation performed as a part of the erase operation. The erase verification operation is an operation to determine whether the threshold voltage of the memory cell transistor MT returned to the Er state, by reading the data after the erase operation. That is, the erase verification operation is an operation to check whether the data is erased. When the threshold voltage of each memory transistor MT in the selected block BLK returns to the Er state, the block BLK is determined to be in a pass state (Pass). The block BLK determined to be in the pass state is then prohibited from being erased. On the other hand, when the threshold voltage of each memory cell transistor MT in the selected block BLK did not return to the Er state, the block BLK is determined to be in a fail state (Fail). The erase operation and the erase verification operation are repeatedly executed on the block BLK determined to be in the fail state so that the threshold voltage of each memory transistor MT in the block BLK returns to the Er state. The set of the erase operation and the erase verification operation is called a loop. The operation of repeating a plurality of loops is referred to as an erase sequence. The block BLK that is not determined to be in the pass state even when the erase operation was performed under predetermined conditions (for example, a predetermined number of executions) is treated as a defective block and prohibited from being used. Preparatory operations such as the calculation of the voltage VERA and pre-program operations may be performed prior to a first erase operation. The pre-program operation is, for example, an operation to write data to the block BLK to be erased and raise the threshold to prevent the memory cell to which the data is not written from being excessively erased by the erase operation.

### (2-2. Erase Operation in Comparative Example)

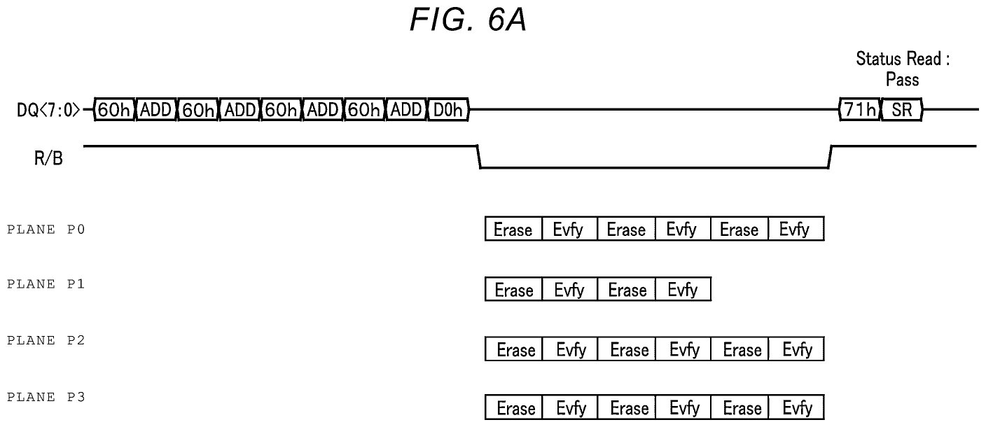

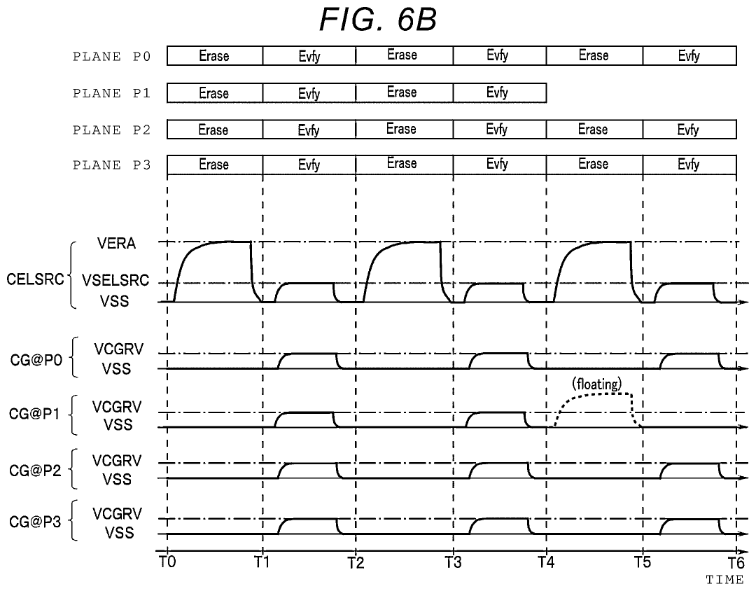

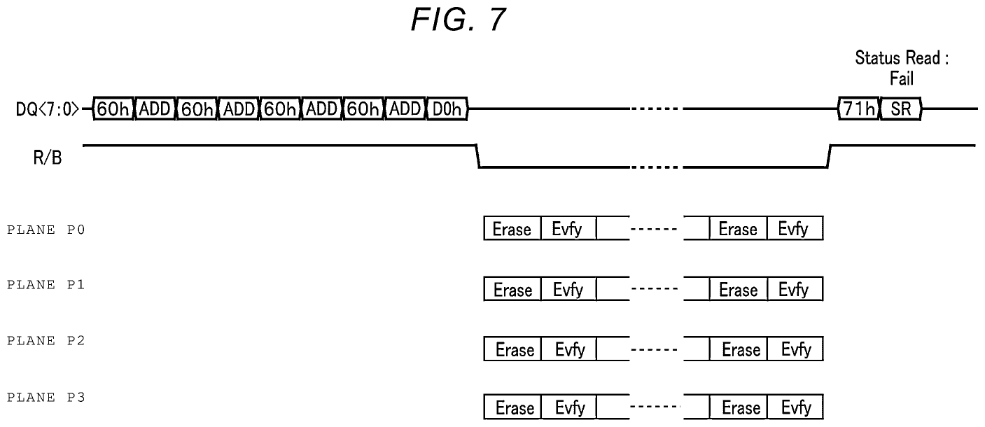

Prior to the description of the erase operation in the present embodiment, the erase operation in a comparative example will be described. Hereinafter, using FIGS. 6A, 6B, and 7, the erase operation for a non-volatile memory of the comparative example will be described. The non-volatile memory of the comparative example is provided with a memory unit MU provided with four planes P0 to P3, similar to the non-volatile memory of the embodiment illustrated in FIG. 2. FIGS. 6A and 7 are diagrams illustrating the command sequence and operation of each plane in a chronological order in the comparative example. In FIGS. 6A and 7, the commands transmitted and received using the signals DQ<7:0> (DQ0 to DQ7), the waveform of the ready busy signal/RB, and the operation of the planes P0 to P3 are illustrated in time series. FIG. 6B is a diagram illustrating a voltage change of each wiring in the comparative example. Specifically, a voltage change of each wiring in the operation of FIG. 6A is illustrated.

First, a case where the erase operation is normally performed will be described using FIGS. 6A and 6B. As illustrated in FIG. 6A, when the ready busy signal/RB is in the high state, that is, the non-volatile memory 2 is in the ready state, a set including a command 60h instructing block erase and an address ADD of the target plane and the target block are transmitted as the signal DQ from the memory controller 1 to the non-volatile memory 2. In a non-volatile memory provided with a plurality of planes, when an erase instruction is input from the memory controller 1, the erase operation is performed for all planes. For example, in the case of the non-volatile memory 2 provided with four planes, the signal is transmitted in the order of the command 60h, the address ADD (the address of the erase target block BLK in the plane 0), the command 60h, the address ADD (the address of the erase target block BLK in the plane 1), the command 60h, the address ADD (the address of the erase target block BLK in the plane 2), the command 60h, and the address ADD (the address of the erase target block BLK in the plane 3). Following the signals, when a command D0h that is an execution command is transmitted, the ready busy signal/RB switches from high to low, and the non-volatile memory 2 switches to the busy state. Then, the erase operation is started for the designated block BLK of each of the planes P0 to P4. The following erase operation is performed based on the instructions of the sequencer 27.

FIG. 6A illustrates a case where the planes P0, P2, and P3 enter a pass state after three erase operations, and the plane P1 enters a pass state after two erase operations. Here, each signal line becomes a waveform as illustrated in FIG. 6B. That is, in the erase operation starting from times T0, T2, and T4, the voltage VERA is applied to the source line CELSRC, and in the erase verification operation starting from times T1, T3, and T5, the voltage VCELSRC is applied to the source line CELSRC. The applied voltage is lowered to the voltage VSS between the erase operation and the erase verification operation. That is, the source line CELSRC changes in the order of the voltage VSS, the voltage VERA, the voltage VSS, the voltage VCELSRC, the voltage VSS, . . . . The signal line CG that supplies the voltage to the word line WL of the plane P0 (illustrated as CG@P0 in FIG. 6B), the signal line CG that supplies the voltage to the word line WL of the plane P1 (illustrated as CG@P1 in FIG. 6B), the signal line CG that supplies the voltage to the word line WL of the plane P2 (illustrated as CG@P2 in FIG. 6B), and the signal line CG that supplies the voltage to the word line WL of the plane P3 (illustrated as CG@P3 in FIG. 6B) are applied, for example, with the voltage VSS in the erase operation starting from the times TO, T2, and T4. The voltage VCGRV is applied to the signal lines CG in the erase verification operation starting from times T1, T3, and T5. The voltage applied to each signal line CG in the erase operation may be a voltage other than the voltage VSS. The voltage applied to each signal line CG in the erase operation may be, for example, the voltage VPASS, the voltage VCC (driving power supply voltage VDD of the circuit), or the like. Regardless of the type of voltage, the waveform is the same as in FIG. 6B.

Since three erase operations are performed on the planes P0, P2, and P3, the pulse of the voltage VCGRV appears three times at the timing of the erase verification operation. Since the plane P1 enters a pass state after two erase operations, the pulse of the voltage VCGRV appears twice. When the third erase operation is performed on the planes P0, P2, and P3, the plane P1 is in a non-selected state where the erase operation is not performed. In the non-selected state, the signal line CG is in a floating state. Therefore, due to the capacitive coupling of the signal line CG and the source line CELSRC, while the voltage VERA is applied to the source line CELSRC, the voltage of the signal line CG is also increased as shown by the dotted line in FIG. 6B.

Referring back to FIG. 6A, when the selected block BLK of all the planes P0 to P3 is determined to be in the pass state, the erase operation ends, and the ready busy signal/RB is switched from low to high. Then, a command 71h that is a read status command and a command SR representing the status are transmitted as the signal DQ from the non-volatile memory 2 to the memory controller 1. The command 71h and the command SR are examples, and the status may be transmitted using other commands. In FIG. 6A, a “pass” command indicating that the block BLK entered the pass state on all of the planes P0 to P3 is transmitted as the command SR.

Next, the case where a leakage current occurs on any plane (for example, plane P2) and the erase operation is not normally performed will be described using FIG. 7. As described above, when four sets including the command 60h and the address ADD are transmitted as the signal DQ from the memory controller 1 to the non-volatile memory 2, and then the command D0h is transmitted, the erase operation is started for the designated block BLK of each of the planes P0 to P3. For example, when a defect occurs in the memory cell array 23 of the plane P2 and a leakage current is generated from the source line CELSRC to the word line WL, the source line CELSRC cannot be held at the voltage VERA in the erase operation. When the source line CELSRC is lowered from the voltage VERA, holes for recombining with the charge of the charge storage layer 336 cannot be sufficiently generated. That is, even when the erase operation is repeated, the block BLK cannot be put into a pass state. When the erase operation is performed under predetermined conditions (for example, a predetermined number of executions), the erase operation ends, and the command 71h and the command SR are transmitted in order from the non-volatile memory 2 to the memory controller 1. Since the source line CELSRC is common to all of the planes P0 to P3, even when the erase operation is repeated, the block BLK is not determined to be in the pass state in all of the planes P0 to P3. Here, it is determined that erase status fail (ESF) occurred, and a “Fail” command is transmitted as a command SR indicating that the block BLK is in a fail state in all planes P0 to P3. Then, the selected block BLK of all planes P0 to P3 is treated as a defective block and prohibited from being used. In the present embodiment, the determination of ESF is referred to as an ESF determination.

As such, in the comparative example, for example, only the block BLK of the plane P2 is defective, and although the block BLK of the planes P0, P1, and P3 is normal, the block BLK of all the planes P0 to P3 is classified as a defective block. In other words, the number of available memory cells decreases and the use efficiency of memory cells may decrease as the block BLK that is originally usable became unusable.

### (2-3. Erase Operation in Present Embodiment)

Next, the erase operation in the present embodiment will be described. The present embodiment is different from the above-described comparative example in that the detection operation of the defective block is performed during the period of the erase operation. In the present embodiment, a detection operation of a defective block (Detect) refers to a series of operations from a detection operation to a determination operation. In the present embodiment, the detection circuit 282 is used to detect the leakage current of the erase target block BLK as the detection operation. Specifically, when the voltage VSS is applied to the signal line CG and the voltage VERA is applied to the source line CELSRC, whether current flows to the signal line CG is detected. The detection of the leakage current is performed for each of the planes P0 to P3. In the present embodiment, the validity of the erase sequence for the erase target block BLK is determined as a determination operation. When the erase sequence is valid, the threshold voltage of each memory transistor MT in the erase target block BLK is at the Er state. When the erase sequence is not valid, the threshold voltage of each memory transistor MT in the erase target block BLK is not at the Er state. The determination operation is performed, for example, at the sequencer 27. The block BLK in which the leakage current is detected by the detection operation is determined to be in a fail state (determined that the erase sequence is not valid) in the determination operation of the sequencer 27, and subsequent erase operation or erase verification operation is not performed.

The execution timing of the detection operation during the erase operation is roughly divided into three categories: (a) before the first erase operation is performed, (b) immediately after or during the first erase operation, and (c) after an ESF determination is made internally. Hereinafter, the erase operation of the present embodiment will be described for each execution timing. In the description of the erase operation in the following embodiments, it is assumed that the block BLK of the plane P2 is defective due to defects, or the like, and the planes P0, P1, and P3 are normal.

### (a) Before the First Erase Operation is Performed

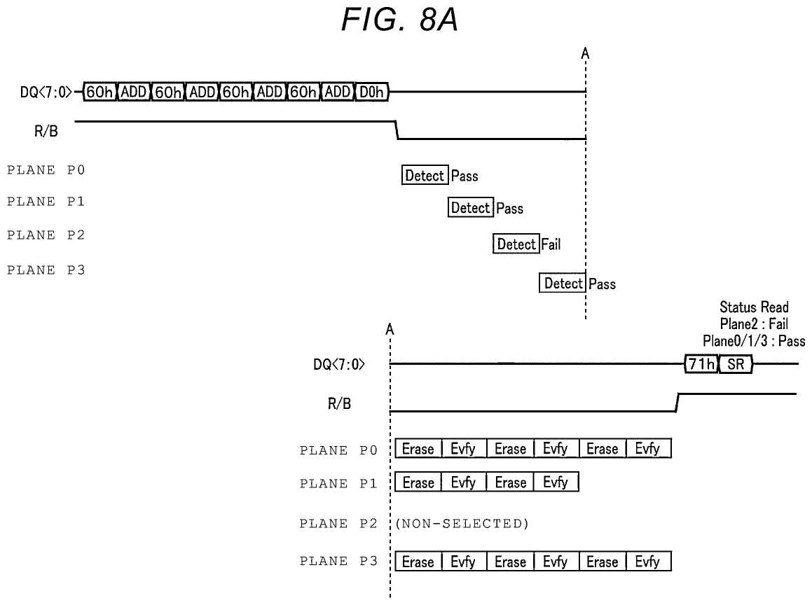

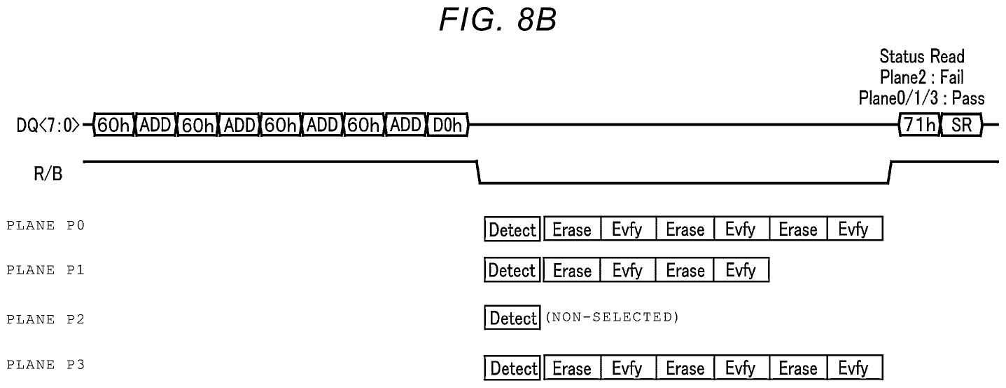

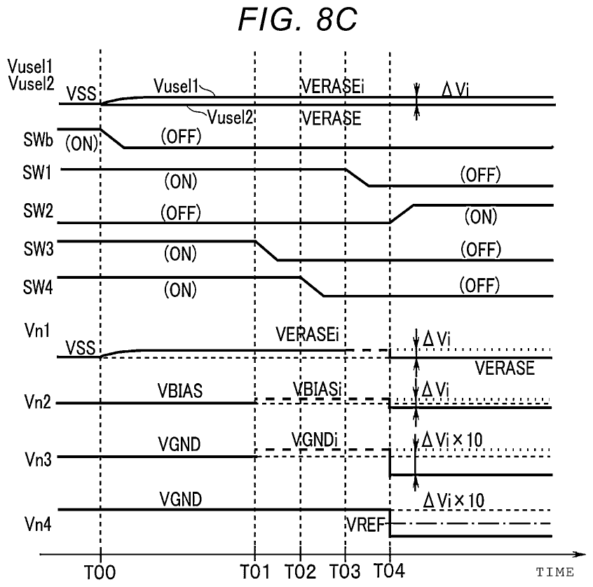

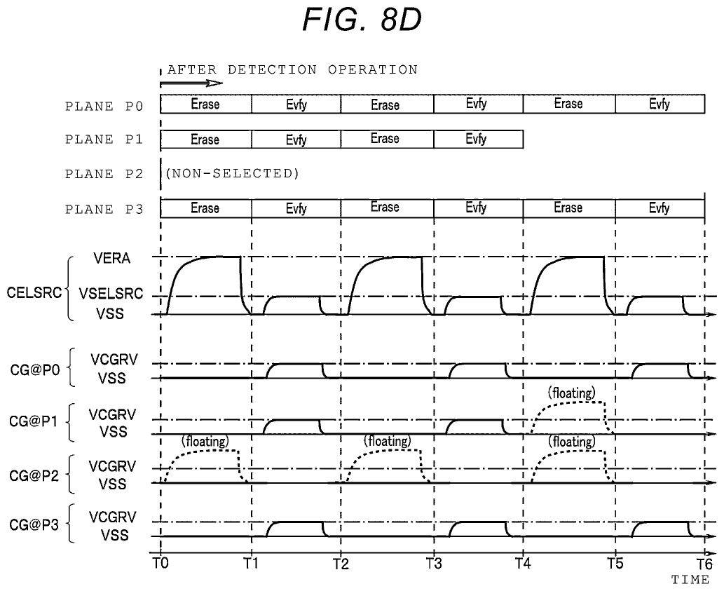

The erase operation in which the detection operation is performed before the first erase operation is performed will be described using FIGS. 8A and 8B. FIGS. 8A and 8B are diagrams illustrating an example of the command sequence and operation of each plane according to the first embodiment. Although FIG. 8A is divided into two stages of upper and lower stages, the time point indicated by a dotted line A in the upper stage and the time point indicated by a dotted line A in the lower stage represent the same time point. In other words, the operations shown in the upper stage and the operations shown in the lower stage are performed continuously.

As illustrated in FIG. 8A, when four sets including the command 60h and the address ADD are transmitted as the signal DQ from the memory controller 1 to the non-volatile memory 2, and then the command D0h is transmitted, the erase operation is started for the designated block BLK of each of the planes P0 to P3. Then, first, the detection operation is performed for the block BLK of the plane P0. That is, the voltage VERA is applied to the source line CELSRC, the voltage VSS is applied to the signal line CG of the plane P0, the signal lines CG of the planes P1 to P3 are in a floating state, and the leakage current is detected using the detection circuit 282 provided in the plane P0.

FIG. 8C is a diagram illustrating an example of a voltage change of each wiring of the detection circuit according to the first embodiment. FIG. 8C also illustrates a temporal change in the voltage of the control signal input to several switches SW. Before the start of the leakage current detection operation illustrated in FIG. 8C, for example, the switch SWb is turned on, and the nodes NCG1 and NCG2 are stable at the voltage VSS, respectively. The control signal is input to the switch SW1 at the high (H) level, and the switch SW1 is turned on. The control signal is input to the switch SW2 at the low (L) level, and the switch SW2 is turned off. Since the switch SW1 is turned on and the switch SW2 is turned off, the switch SW1 in the on state transmits the voltage Vusel1 to the node N1. As a result, the voltage Vn1 is also stable at the voltage VSS. The control signal is input to the switch SW3 at the H level, and the switch SW3 is turned on. The switch SW3 in the on state transmits the voltage VBIAS to the node N2. As a result, the voltage Vn2 is stable at the voltage VBIAS. Since the amplifier circuit AMP outputs the signal resulting from the amplification of the voltage Vn2 based on the voltage VBIAS on the node N3, the voltage Vn3 is 0 V, and is shown as a voltage VGND in FIG. 8C. The control signal is input to the switch SW4 at the H level, and the switch SW4 is turned on. The switch SW4 in the on state transmits the voltage VGND to the node N4. As a result, the voltage Vn4 is also stable at the voltage VGND.

From time T00 to the completion of the leakage current detection operation, the control signal is input to the switch SWb at the L level, and the switch SWb is turned off. At time T00, an operation is started to control the voltage output by the pump unit 281B to the node NCG2 connected to the word line WL to a voltage VERASE (for example, the voltage VSS) at the time of the erase operation. As a result, the voltage Vusel2 becomes stable at the voltage VERASE. The voltage output by the pump unit 281B to the node NCG2 is transmitted to the node NCG1, that is electrically connected to the node NCG2. As a result, the voltage Vusel1 becomes stable at a voltage VERASEi during the erase operation. Here, the case where the leakage current is flowing into the word line WL will be described. The leakage current flows from the node NCG1 to the node NCG2, for example, via the resistor RL. Therefore, a voltage drop due to the leakage current occurs in the resistor RL. Here, the voltage VERASEi is higher than the voltage VERASE by the amount of the voltage drop. In FIG. 8C, the potential difference between the voltage VERASEi and the voltage VERASE is shown as ΔVi.

The level of the control signal input to the switches SW1, SW2, SW3, and SW4 is maintained. Since the switch SW1 is turned on, the voltage Vn1 changes according to the voltage Vusel1 and becomes stable at the voltage VERASEi. Although description is omitted in FIG. 8C, at time T00, the voltage applied to the source line CELSRC is changed from the voltage VSS to the voltage VERA.

Then, at time T01, the control signal input to the switch SW3 is changed from the H level to the L level, and the switch SW3 switches from the on state to the off state. For example, in response to the switch SW3 being turned off, the voltage Vn2 changes and becomes stable at a voltage VBIASi. In response to the change in the voltage Vn2, the voltage Vn3 changes and becomes stable at a voltage VGNDi. The potential difference between the voltage VGNDi and the voltage VGND is 10 times the voltage difference between the voltage VBIASi and the voltage VBIAS, for example, due to amplification by the amplifier circuit AMP. As such, when the switch SW3 is turned off, the fixation of the voltage Vn2 at the voltage VBIAS is released, and the voltage Vn2 and the voltage Vn3 are affected by the change of the voltage Vn1.

Then, at time TO2, the control signal input to the switch SW4 is changed from the H level to the L level, and the switch SW4 switches from the on state to the off state. When the switch SW4 is turned off, the fixation of the voltage Vn4 at the voltage VGND is released, and when the voltage Vn3 changes, the voltage Vn4 is affected by the change. At the subsequent time TO3, the control signal input to the switch SW1 is changed from the H level to the L level, and the switch SW1 switches from the on state to the off state.

Then, at time TO4, the control signal input to the switch SW2 is changed from the L level to the H level, and the switch SW2 switched from the off state to the on state. Since the switch SW1 is turned off and the switch SW2 is turned on, the switch SW2 in the on state transmits the voltage Vusel2 to the node N1. As a result, the voltage Vn1 is stable at the voltage VERASE like the voltage Vusel2. As such, the voltage Vn1 drops from the voltage VERASEi by the voltage difference ΔVi.

In response to the voltage Vn1 dropping by the voltage difference ΔVi, the voltage Vn2 drops from the voltage VBIASi by the voltage difference ΔVi. It is because the capacitive element C1 maintains a potential difference between the first electrode and the second electrode of the capacitive element C1 when the switch SW3 is turned off.

In response to the voltage Vn2 dropping by the voltage difference ΔVi, the voltage Vn3 drops from the voltage VGNDi. The change amount of the voltage Vn3 is 10 times the voltage difference ΔVi, that is the change amount of the voltage Vn2. It is because the amplifier circuit AMP outputs the signal resulting from the amplification of the voltage Vn2 based on the voltage VBIAS on the node N3.

In response to the voltage Vn3 dropping by 10 times the voltage difference ΔVi, the voltage Vn4 drops from the voltage VGND by 10 times ΔVi. It is because the capacitive element C2 maintains a potential difference between the first electrode and the second electrode of the capacitive element C2 when the switch SW4 is turned off.

The comparator CMP outputs a signal FLG resulting from the comparison of the voltage Vn4 and the voltageVREF. Due to the change in the voltage Vn4 at time TO4, when the voltage Vn4 falls below the voltage VREF, as illustrated in FIG. 8C, the level of the signal FLG output from the comparator CMP changes. The change in the level of the signal FLG means that a leakage current flowing into the word line WL is detected.

When the leakage current is not detected, the block BLK is determined to be normal (Pass) at the sequencer 27. On the other hand, when the leakage current is detected, the block BLK is determined to be defective (Fail). In the above description, the current value detected by the detection circuit 282 is output to the sequencer 27 and the defective block is determined by the sequencer 27, but the determination of the defective block caused by the leakage current may be performed by the detection circuit 282. When the detection operation for the block BLK of the plane P0 ends, the detection operation is also sequentially performed on the block BLK of the other planes P1 to P3.

When the detection operation for the block BLK of all planes P0 to P3 ends, the erase operation is performed only for the block BLK determined to be normal. FIG. 8D is a diagram illustrating an example of a voltage change of each signal line according to the first embodiment. Specifically, the voltage change of each signal line in the erase operation after the detection operation of FIG. 8A ends is illustrated. For example, in the detection operation, when the block BLK of the plane P2 is determined to be defective, in the erase operation starting from the times TO and T2, the voltage VERA is applied to the source line CELSRC, the voltage VSS is applied to the signal lines CG of the planes P0, P1, and P3, and the signal line CG of the plane P2 is in a floating state. In other words, it is possible to not select the block BLK of the plane P2 and selectively perform the erase operation on the block BLK of the other planes P0, P1, and P3. Since the plane P1 enters a pass state after two erase operations, the third erase operation is not performed. In other words, in the erase operation starting from time T4, the voltage VERA is applied to the source line CELSRC, the voltage VSS is applied to the signal lines CG of the planes P0 and P3, and the signal lines CG of the planes P1 and P2 are in a floating state.

The defective block (plane P2) also does not perform the erase verification operation. In other words, in the erase verification operation starting from times T1 and T3, the voltage VCGRV is applied to the signal lines CG of the planes P0, P1, and P3, and the voltage VSS is applied to the signal line CG of the plane P2. Since the plane P1 enters a pass state after two erase operations, the third erase verification operation is not performed. That is, in the erase verification operation starting from time T5, the voltage VCGRV is applied to the signal lines CG of the planes P0 and P3, and the voltage VSS is applied to the signal lines CG of the planes P1 and P2. When all of the block BLK of the planes P0, P1, and P3 on which the erase operation was performed is determined to be in the pass state, the erase operation ends. Then, the command 71h and the subsequent command SR are transmitted as the signal DQ from the non-volatile memory 2 to the memory controller 1. In FIG. 8A, a command indicating that the block BLK is in the pass state on all of the planes P0, P1, and P3, and the block BLK on the plane P2 entered the fail state is transmitted as the command SR.

As such, according to the present embodiment, in the erase operation that erases the block BLK of the plurality of planes in parallel, the detection operation to detect whether there is a leakage current from the source line CELSRC to the signal line CG is performed before the first erase operation. By the detection operation, defective blocks can be detected. Therefore, the erase operation can be performed selectively on the blocks other than the defective blocks. By not selecting the defective block, the voltage drop of the source line CELSRC during the erase operation can be reduced and the voltage VERA can be maintained. Therefore, the blocks other than the defective blocks can be put into a pass state. Therefore, the reduction in the number of available memory cells can be prevented and the memory cells can be used efficiently.

The operation illustrated in FIG. 8B is different from the operation illustrated in FIG. 8A described above in that the detection operation performed before the first erase operation is performed in parallel on all of the planes P0 to P3. The configuration of the non-volatile memory 2 performing the operation illustrated in FIG. 8B is similar to the configuration of the non-volatile memory 2 performing the operation of FIG. 8A. That is, the detection circuit 282 provided on the plane P0 can detect the leakage current from the source line CELSRC to the signal line CG@P0. The detection circuit 282 provided on the plane P1 can detect the leakage current from the source line CELSRC to the signal line CG@P1. The detection circuit 282 provided on the plane P2 can detect the leakage current from the source line CELSRC to the signal line CG@P2. The detection circuit 282 provided on the plane P3 can detect the leakage current from the source line CELSRC to the signal line CG@P3. By using the detection circuit 282 of each of the planes P0 to P3 to detect the leakage current of the respective block BLK in parallel, it is possible to shorten the time required for the erase operation.

(b) Immediately after or During the First Erase Operation

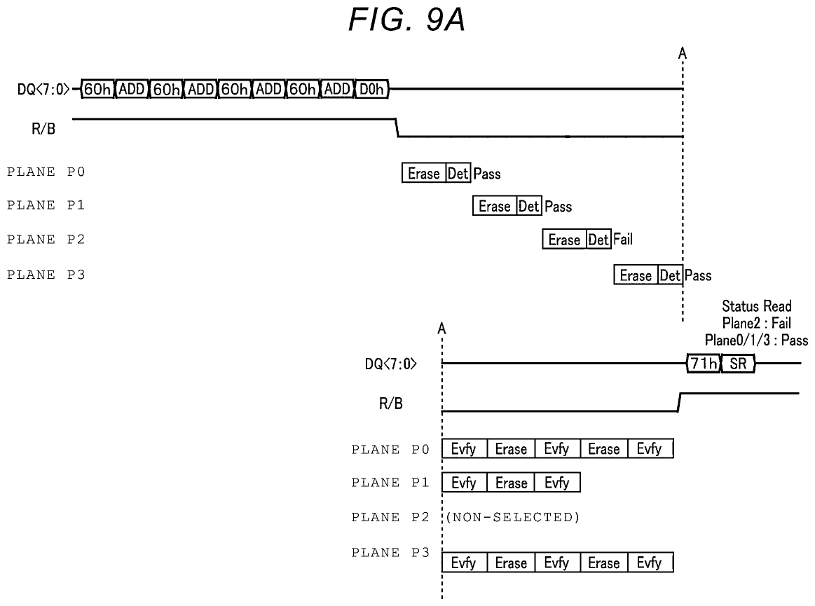

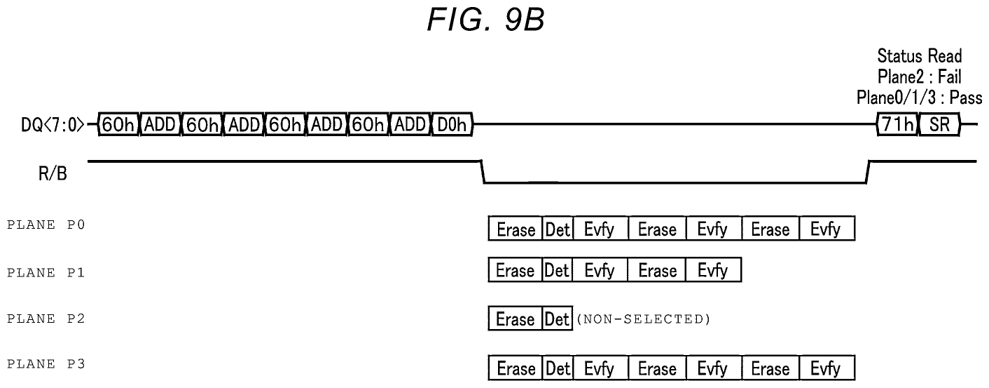

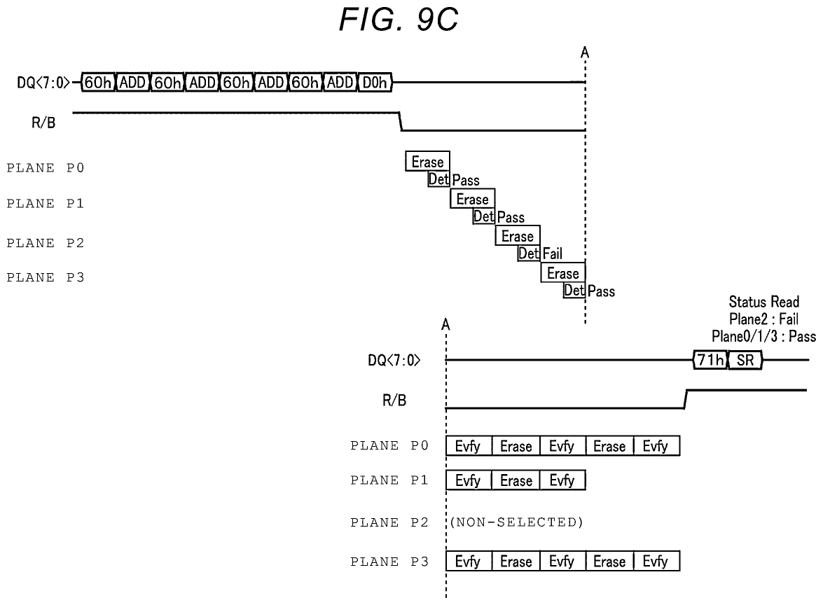

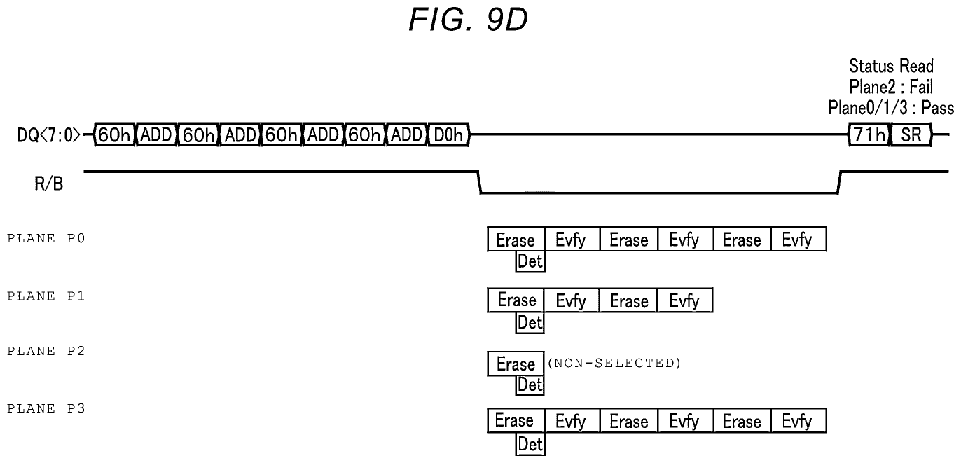

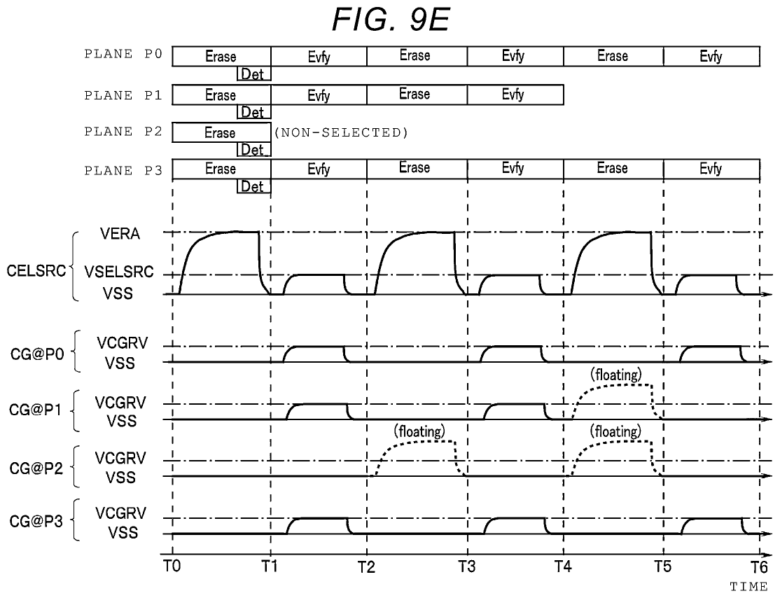

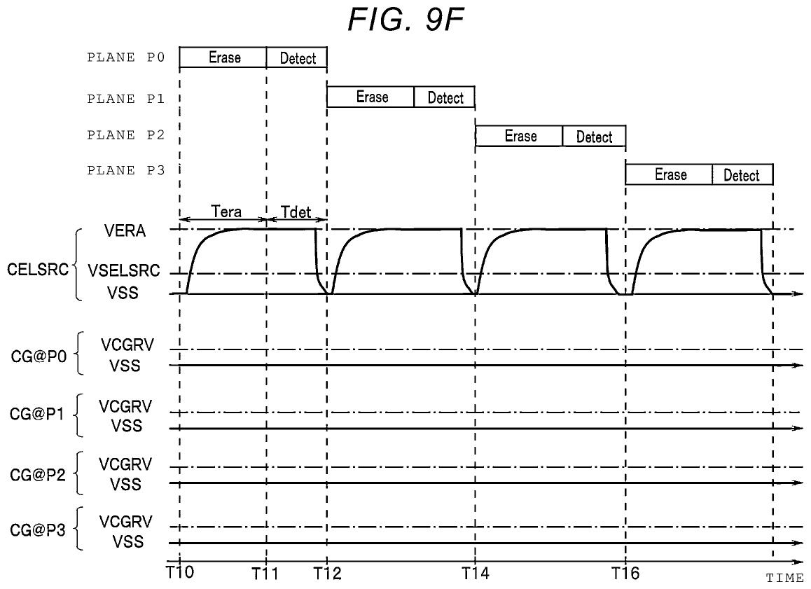

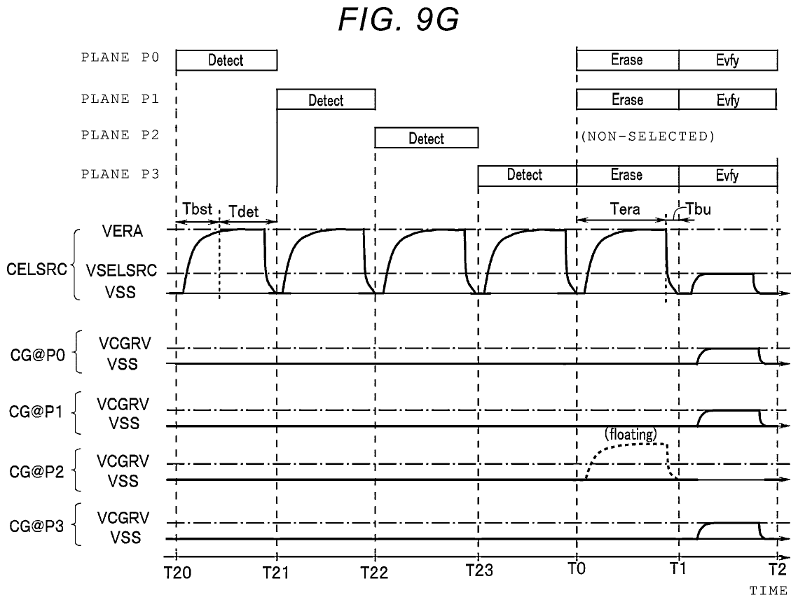

The erase operation in which the detection operation is performed immediately after the first erase operation will be described using FIGS. 9A and 9B. FIGS. 9A and 9B are diagrams illustrating an example of the command sequence and operation of each plane according to the first embodiment. Although FIG. 9A is divided into two stages of upper and lower stages, the time point indicated by a dotted line A in the upper stage and the time point indicated by a dotted line A in the lower stage represent the same time point. That is, the operations shown in the upper stage and the operations shown in the lower stage are performed continuously.

As illustrated in FIG. 9A, when four sets including the command 60h and the address ADD are transmitted as the signal DQ from the memory controller 1 to the non-volatile memory 2, and then the command D0h is transmitted, the erase operation is started for the designated block BLK of each of the planes P0 to P3. FIG. 9F is a diagram illustrating an example of a voltage change of each signal line according to the first embodiment. Specifically, FIG. 9F illustrates the voltage change of each signal line until the detection operation of FIG. 9A ends. First, at time T10, the first erase operation is started for the block BLK of the plane P0. When the erase operation ends at time T11, the detection operation is started while the voltage of the source line CELSRC is maintained to the voltage VERA without being lowered to the voltage VSS. The detection operation by the detection circuit 282 is similar to the operation described above using FIG. 8A. When the detection operation of plane P0 ends at time T12, the detection operation is also sequentially performed on the block BLK of the other planes P1 to P3.

When the detection operation for the block BLK of all planes P0 to P3 ends, the erase verification operation is performed only for the block BLK determined to be normal. When the block BLK of the planes P0, P1, and P3 on which the erase verification operation was performed is determined to be in the pass state, the erase operation ends. Then, the command 71h and a subsequent command SR is transmitted as the signal DQ from the non-volatile memory 2 to the memory controller 1. In FIG. 9A, a command indicating that the block BLK on all of the planes P0, P1, and P3 is in the pass state, and the block BLK on the plane P2 entered the fail state is transmitted as the command SR.

FIG. 9G is a diagram illustrating an example of a voltage change of each signal line according to the first embodiment. Specifically, the voltage change of each signal line is illustrated from the start of the detection operation of FIG. 8A to the end of the first erase verification operation. As illustrated in FIG. 9G, when the detection operation is performed before the erase operation, it takes a period Tbst to boost the source line CELSRC to the voltage VERA after starting the detection operation at time T20. After the source line CELSRC is boosted to the voltage VERA, the detection of the leakage current is performed in a period Tdet. In other words, the time required for the detection operation is the period Tbst +period Tdet.

In contrast, when the detection operation is performed immediately after the first erase operation, as illustrated in FIG. 9F, it is not necessary to boost the source line CELSRC by executing the detection operation while the source line CELSRC maintains the voltage VERA after the first erase operation is performed. In other words, since the period Tbst is unnecessary, the time required for the detection operation is the period Tdet. Accordingly, compared to FIG. 8A, the time required for the detection operation can be shortened, and the time required for the erase operation can also be shortened. The first erase operation may be performed in parallel on all planes P0 to P3, as illustrated in FIG. 9B. The detection operation may also be performed in parallel on all planes P0 to P3. By executing the detection operations in parallel on all planes P0 to P3, respectively, the time required for the erase operation can be further shortened.

Next, the erase operation when the detection operation is performed while the first erase operation is performed will be described using FIGS. 9C and 9D. FIGS. 9C and 9D are diagrams illustrating an example of the command sequence and operation of each plane according to the first embodiment. Although FIG. 9C is divided into two stages of upper and lower stages, the time point indicated by a dotted line A in the upper stage and the time point indicated by a dotted line A in the lower stage represent the same time point. In other words, the operations shown in the upper stage and the operations shown in the lower stage are performed continuously.

As illustrated in FIG. 9C, when the erase operation is started for the designated block BLK of each of the planes P0 to P3, first, the first erase operation is performed for the block BLK of the plane P0. After the erase operation is progressed for a predetermined time, the detection operation is started while the erase operation is performed. The detection operation is also performed until the erase operation ends. The detection operation by the detection circuit 282 is similar to the operation described above using FIG. 8A. When the first erase operation and the detection operation of the plane P0 end, the block BLK of the other planes P1 to P3 also sequentially performs the first erase operation and the detection operation.

In the detection operation, the voltage applied to the source line CELSRC and the voltage applied to the signal line CG are the same as the voltages applied to the respective lines in the erase operation. The detection operation does not affect the action of the erase operation. Therefore, the erase operation and the detection operation can be executed in parallel. By performing the detection operation in parallel with the first erase operation, the erase time can be shortened compared to the case where the detection operation is performed immediately after the erase operation as illustrated in FIG. 9A.

The first erase operation including the detection operation may be performed in parallel on all planes P0 to P3, as illustrated in FIG. 9D. By executing the operations in parallel, the time required for the erase operation can be further shortened. FIG. 9E is a diagram illustrating an example of a voltage change of each wiring according to the first embodiment. Specifically, the voltage change of each wiring in the operation of FIG. 9D is illustrated. For the erase operation in which the voltage of the signal line CG first becomes a floating state, the voltage of the signal line CG during the erase verification operation immediately before the erase operation is different between the comparative example and the present embodiment. As illustrated in FIG. 6B, in the comparative example, in the erase operation starting at time T4, the voltage of the signal line CG@P1 first becomes a floating state. In the immediately preceding erase verification operation, that is, in the erase verification operation starting at time T3, the voltage VCGRV is applied to the signal line CG@P1. In contrast, in the present embodiment, as illustrated in FIG. 9E, in the erase operation starting at time T2, the voltage of the signal line CG@P2 first becomes a floating state. In the immediately preceding erase verification operation, that is, in the erase verification operation starting at time T1, the voltage VSS is applied on the signal line CG@P2. In the comparative example, the signal line CG is in the floating state during the erase operation when the block BLK is determined to be in the pass state in the erase verification operation. On the other hand, in the present embodiment, even when the block BLK is determined as a defective block in the detection operation, the signal line CG is in a floating state during the erase operation. Therefore, as described above, there is a difference in the voltage of the signal line CG.

### (c) After an ESF Determination is Made Internally

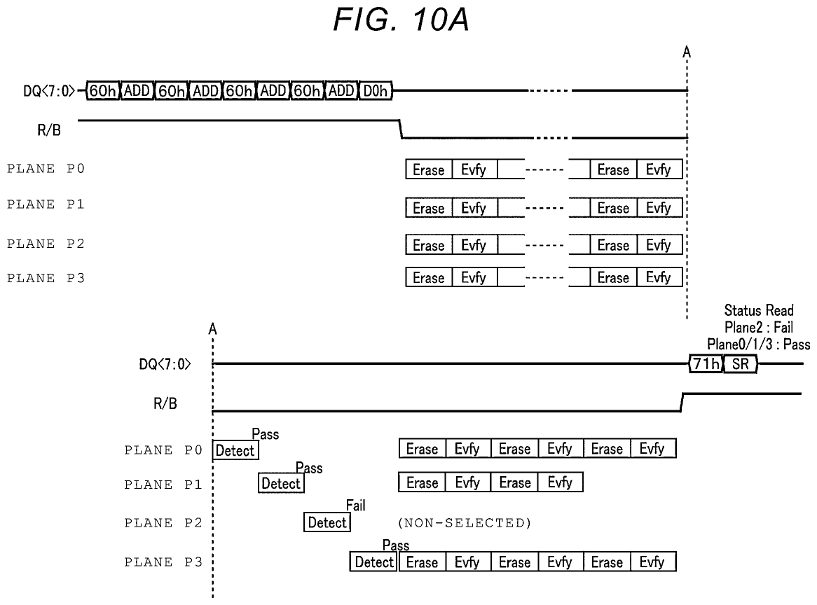

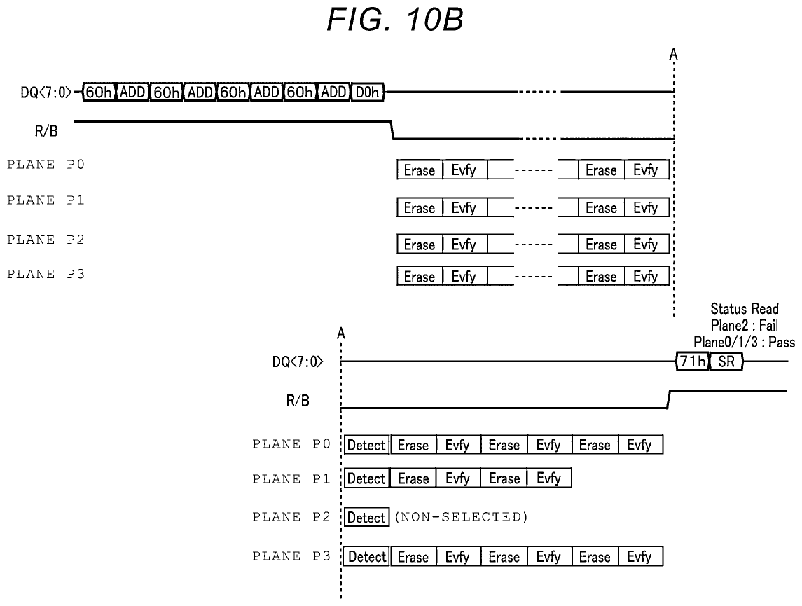

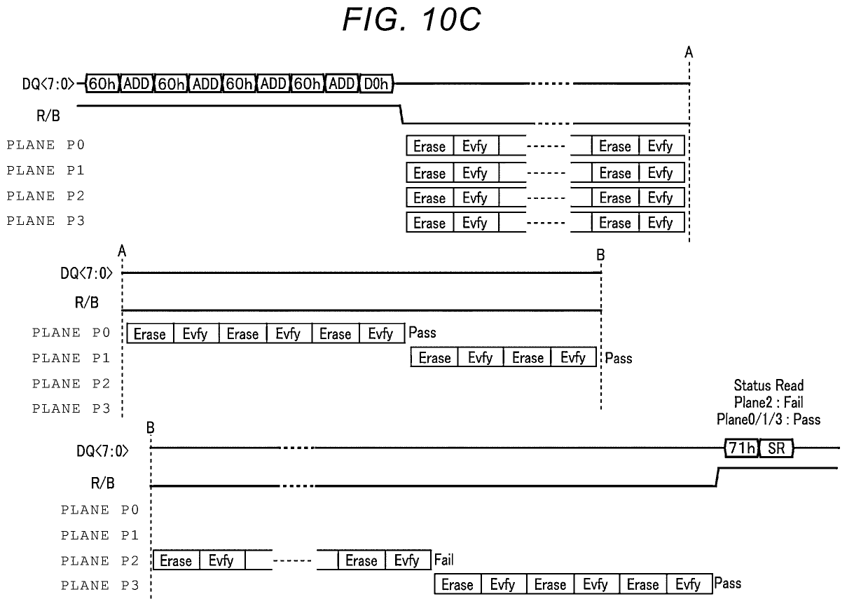

In the present specification, “an ESF determination is made internally” is defined as that an ESF determination is made within the non-volatile memory 2 without the memory controller 1 being involved. When the block BLK of at least one of the plurality of planes P0 to P3 is a defective block, in the erase operation of the comparative example, an ESF determination that determines all the blocks BLK as defective blocks is made and transmitted from the non-volatile memory 2 to the memory controller 1 as the signal DQ. In the present embodiment, the detection operation is performed after the ESF determination is made. The erase operation in which the detection operation is performed after the ESF determination is made internally will be described using FIGS. 10A, 10B, and 10C. FIGS. 10A, 10B and 10C are diagrams illustrating an example of the command sequence and operation of each plane according to the first embodiment. Although FIG. 10A is divided into two stages of upper and lower stages, the time point indicated by a dotted line A in the upper stage and the time point indicated by a dotted line A in the lower stage represent the same time point. In other words, the operations shown in the upper stage and the operations shown in the lower stage are performed continuously.

As illustrated in the upper stage of FIG. 10A, when the erase operation is started, the erase operation and the erase verification operation are repeated a predetermined number of times, as in the comparative example, and the ESF determination is made at the time of the dotted line A. Then, as illustrated in the lower stage, the detection operation is sequentially performed for the selected block BLK of the planes P0 to P3. When the detection operation for the block BLK of all planes P0 to P3 ends, the erase operation and the erase verification operation are selectively performed only for the block BLK determined to be normal. The block BLK determined to be defective in the detection operation is not selected, and neither the erase operation nor the erase verification operation is performed. When all the blocks BLK determined to be normal are determined to be in the pass state, the erase operation is ended. Then, the command 71h and the subsequent command SR are transmitted as the signal DQ from the non-volatile memory 2 to the memory controller 1. In FIG. 10A, a command indicating that the block BLK is in the pass state on all of the planes P0, P1, and P3, and the block BLK on the plane P2 entered the fail state is transmitted as the command SR.

As such, when the detection operation is performed only after the ESF determination is made internally, the detection operation is not performed in the same way as the comparative example when all the blocks BLK are in the pass state. Therefore, when the occurrence rate of the defective block is low, it is possible to shorten the average time of the erase operation compared to the above-described cases (a) and (b), in which the detection operation is always performed for all the erase operations.

The detection operation may be performed in parallel on all planes P0 to P3, as illustrated in FIG. 10B. By executing the detection operation in parallel, the time required for the erase operation can be shortened. As illustrated in FIG. 10C, when the ESF determination is made internally, the normal block BLK may be selectively erased by selecting the planes P0 to P3 one by one and sequentially retrying the erase operation without performing the detection operation. In the case of the operation shown in FIG. 10C, since the detection circuit 282 is not required, the reduction in the number of available memory cells can be prevented without increasing the area of the non-volatile memory 2, and the memory cells can be used efficiently.

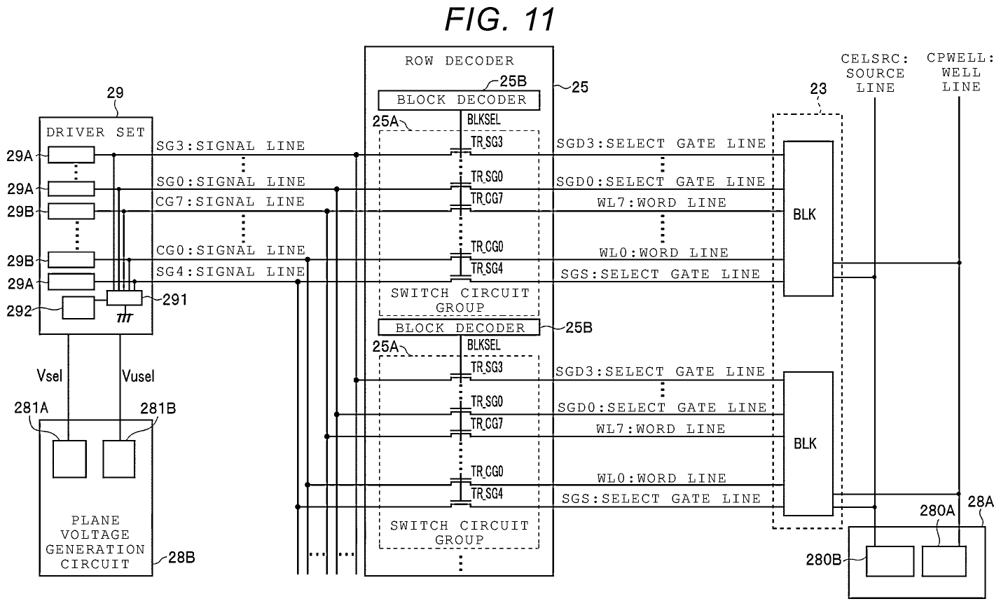

In the above description, the detection circuit 282 is configured to be connected to the pump unit 281B, but the connection position is not limited thereto as long as the leakage current that causes the drop of the voltage VERA applied to the source line CELSRC can be detected. FIG. 11 is a block diagram illustrating another example of the voltage supply path to each wiring of the memory cell array according to the first embodiment. For example, as illustrated in FIG. 11, the detection circuit 282 may be connected to the signal line equalization circuit 291.

When the non-volatile memory 2 is configured with one plane P0, the detection operation is unnecessary. Accordingly, when the non-volatile memory 2 is configured with one plane P0, for example, the sequencer 27 may be configured to automatically stop the detection operation and cause only the erase operation and the erase verification operation to be performed.

Functions that may be executed during normal erase operations, such as Suspend and Resume, can also be executed in the non-volatile memory 2 of the present embodiment.

### Second Embodiment

Next, a second embodiment will be described. A semiconductor memory device according to the present embodiment is different from the above-described first embodiment in a detection circuit and a detection method. Accordingly, the connection position of the detection circuit is also different from the first embodiment. In the detection operation of the present embodiment, a defective block is detected according to the degree of decrease of the voltage VERA applied to the source line CELSRC during the detection operation. The same components are given to the same reference numerals and descriptions thereof are omitted. Hereinafter, differences from the first embodiment will be described.

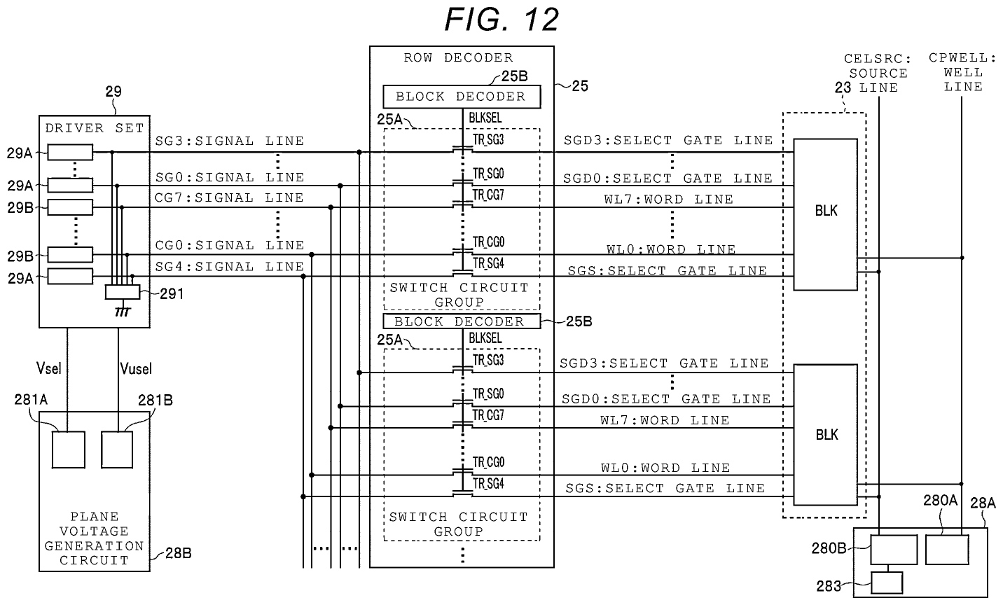

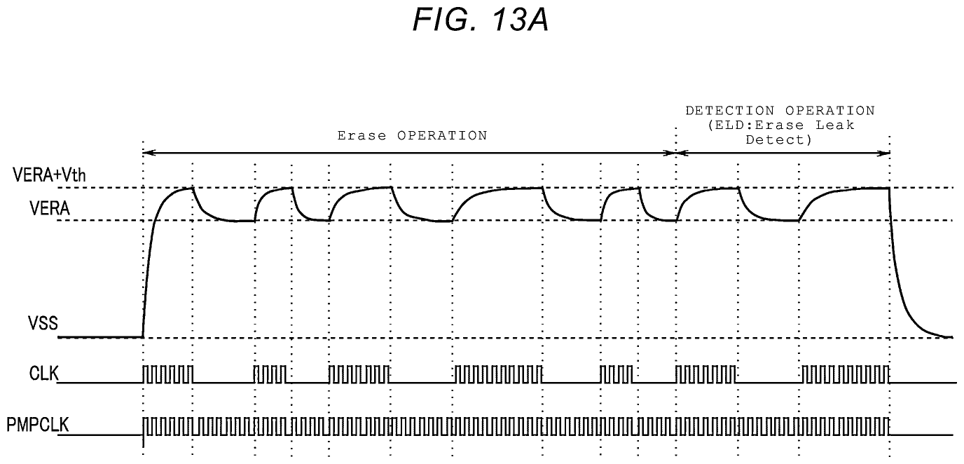

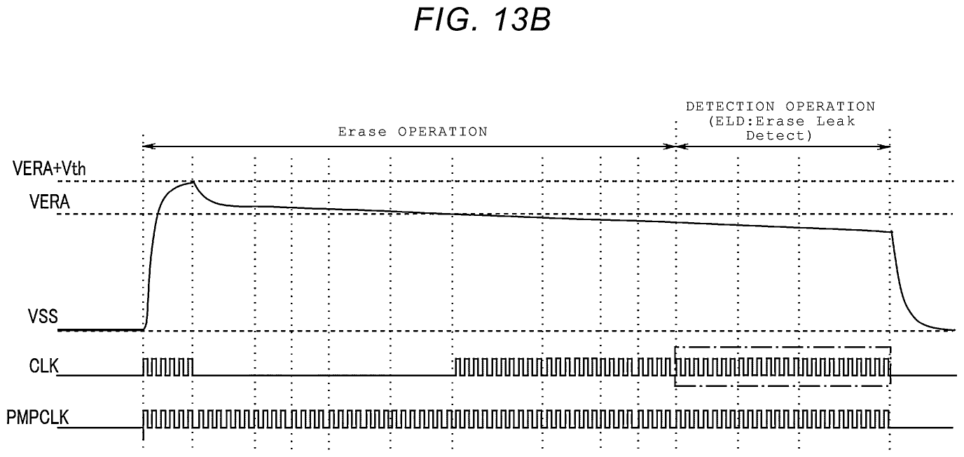

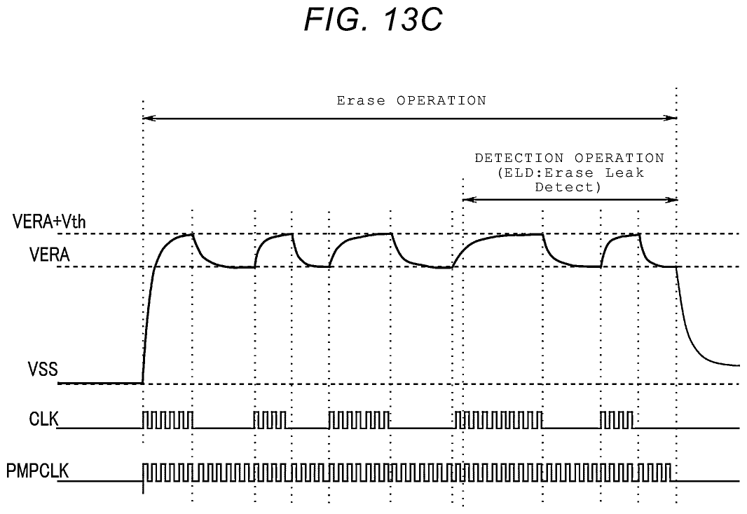

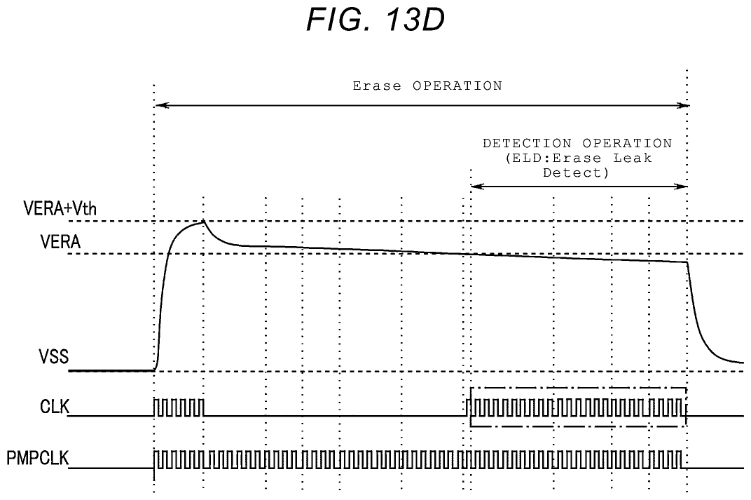

FIG. 12 is a block diagram illustrating an example of the voltage supply path to each wiring of the memory cell array according to the second embodiment. A detection circuit 283 of the present embodiment is connected to the pump unit 280B that supplies voltage to the source line CELSRC. The pump unit 280B drives a charge pump (not illustrated) according to a predetermined cycle of a pump clock signal PMPCLK and performs a continuous boost operation up to the target voltage. The pump unit 280B stops the operation of the charge pump and stops the boost operation when the voltage supplied to the source line CELSRC reaches the target voltage. The pump unit 280B is monitoring the voltage of the source line CELSRC and when the voltage reaches a set lower limit value (trigger voltage), the boost operation is resumed according to the cycle of the pump clock signal PMPCLK. As such, the pump unit 280B repeats the boost operation intermittently according to the voltage of the source line CELSRC. FIGS. 13A to 13D are diagrams illustrating an example of a boost operation control of the pump unit 280B during the erase operation and the detection operation according to the second embodiment. In FIGS. 13A to 13D, a clock signal CLK is a control clock that controls driving of the charge pump and has the same cycle as the cycle of the pump clock signal PMPCLK.

As illustrated in FIG. 13A, for example, during the erase operation, the pump unit 280B sets a voltage higher than the voltage VERA by a predetermined voltage Vth as the target voltage and drives the charge pump by oscillating the clock signal CLK until the voltage of the source line CELSRC reaches the target voltage. When the voltage of the source line CELSRC reaches the target voltage, the oscillation of the clock signal CLK is stopped, and the charge pump stops operation. The voltage of the source line CELSRC gradually decreases during the erase operation. When the voltage of the source line CELSRC reaches the trigger voltage (here, voltage VERA), the pump unit 280B oscillates the clock signal CLK to drive the charge pump again. As such, the pump unit 280B intermittently drives the charge pump to perform the voltage supply operation so that the voltage of the source line CELSRC is maintained at the voltage VERA.

The detection circuit 283 monitors the oscillation operation of the clock signal CLK to detect the voltage drop of the source line CELSRC from the driving state of the charge pump. Specifically, monitoring the oscillation operation of the clock signal CLK is to set the trigger voltage to the voltage VERA and operate the pump unit 280B during a set detection operation period, in the same manner as during the erase operation. The set detection operation period is referred to as, for example, an erase leak detect (ELD). As illustrated in FIG. 13A, when the voltage drop amount of the source line CELSRC is small and normal (when the source line CELSRC can be maintained to not fall below the trigger voltage), the clock signal CLK repeats the oscillation and stop alternately. That is, during the detection operation period, the number of pulses of the clock signal CLK is less than the number of pulses of the pump clock signalPMPCLK, for example, about 50% of the number of pulses of the pump clock signal PMPCLK.

On the other hand, as shown in FIG. 13B, when the voltage drop amount of the source line CELSRC is large and the voltage drop amount is greater than the boost amount even when the charge pump is driven, the source line CELSRC can be boosted up to the target voltage once, but even when the trigger voltage is lower than the trigger voltage and the charge pump is driven again, the voltage of the source line CELSRC cannot be maintained above the trigger voltage. That is, during the detection operation period, the number of pulses of the clock signal CLK is equivalent to the number of pulses of the pump clock signal PMPCLK.

As such, the number of pulses of the clock signal CLK is counted during the detection operation period, and when the ratio to the number of pulses of the pump clock signal PMPCLKis higher than the set value, it is estimated that the voltage drop amount of the source line CELSRC is large, and leakage current paths exist during the erase operation. Accordingly, in the present embodiment, the detection operation is sequentially performed for the set block BLK of the planes P0 to P3 one by one. The timing of the detection operation in the erase operation may be, for example, before the first erase operation as illustrated in FIG. 8A, or immediately after the first erase operation as illustrated in FIG. 9A. As illustrated in FIG. 9C, the detection operation may be performed while the first erase operation is performed. As illustrated in FIG. 10A, the detection operation may be performed only when the erase operation is performed and then ESF determination is made internally.

FIGS. 13A and 13B illustrate an example of a boost operation control of the pump unit 280B when the detection operation is executed immediately after the first erase operation. FIGS. 13C and 13D illustrate an example of a case where the detection operation is performed while the first erase operation is performed. FIGS. 13A and 13C illustrate an operation for a normal block BLK, and FIGS. 13B and 13D illustrate an operation for a defective block.

As such, by detecting the driving state of the charge pump in the pump unit 280B that supplies voltage to the source line CELSRC, defective blocks can be detected, so that the erase operation can be performed selectively on the blocks other than the defective blocks. Therefore, the reduction in the number of available memory cells can be prevented and the memory cells can be used efficiently.

### Third Embodiment

Next, a third embodiment will be described. A semiconductor memory device according to the present embodiment is different from the first and second embodiments in a detection method of a defective block. The same components are given the same reference numerals and descriptions thereof are omitted. Hereinafter, differences from the first and second embodiments will be described.

The detection operation in the present embodiment sequentially performs the normal erase operation and erase verification operation for the set block BLK of the planes P0 to P3 one by one. In the erase verification operation, a percentage of the plurality of memory transistors MT in the selected block BLK whose threshold voltages returned to the Er state is calculated, and when the percentage is less than a pre-set determination criteria, the block BLK is determined to be a defective block. After the determination of whether a defective block is completed for all the planes P0 to P3, the erase operation or the erase verification operation can be performed in parallel for the normal block.

That is, in the detection operation in the present embodiment, since the determination operation of the defective block can be performed in the sequencer 27 or the like using a result of the first erase verification operation, it is not necessary to provide a dedicated detection circuit. Accordingly, the reduction in the number of available memory cells can be prevented and the memory cells can be used efficiently without increasing the area of the non-volatile memory 2. Results of the second and subsequent erase verification operations may be used for the defective block determination operation. The erase operation may also be performed in parallel for all the planes P0 to P3 as in the comparative example, and the above-described detection operation may be performed only when the ESF determination is made internally.

### Fourth Embodiment

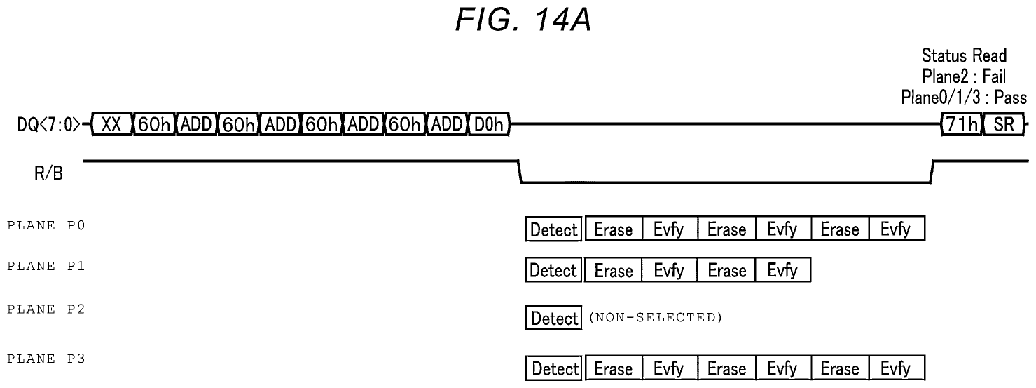

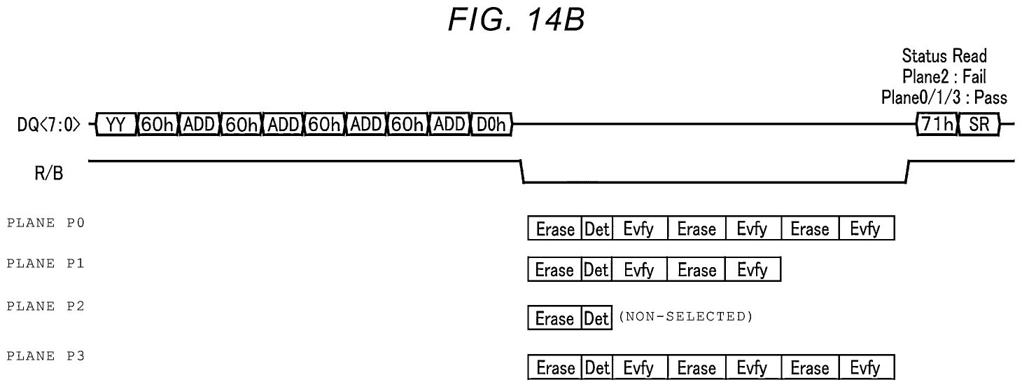

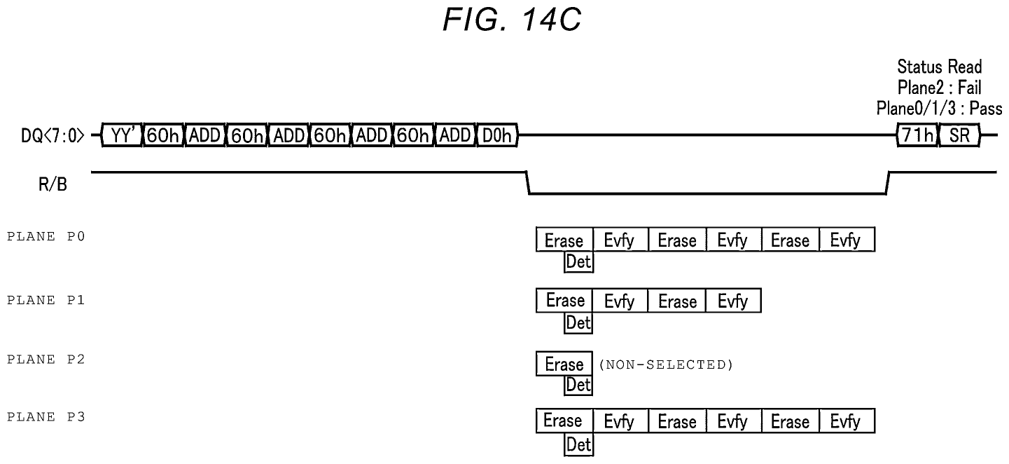

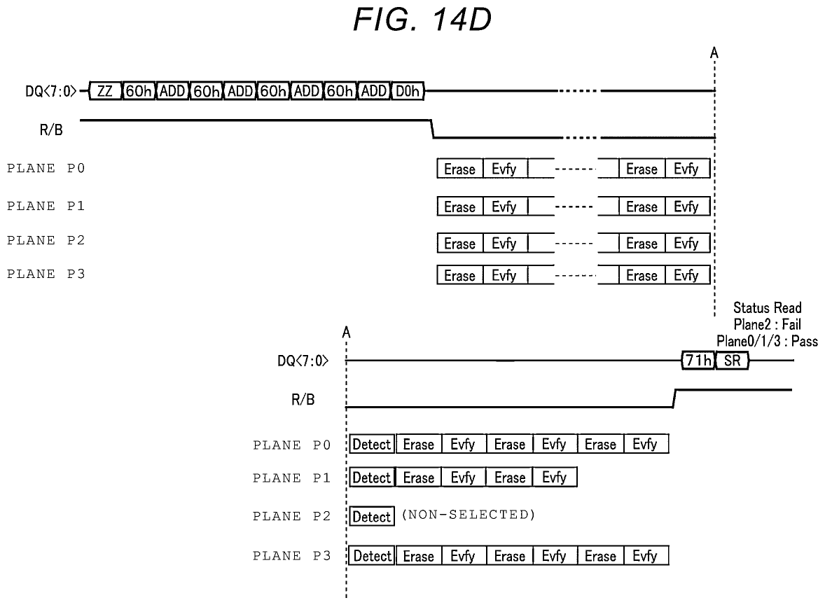

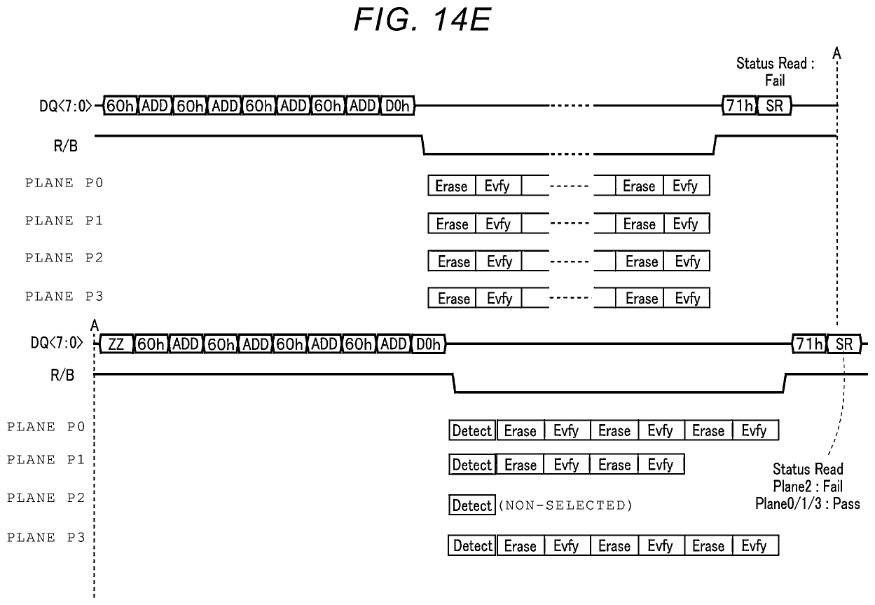

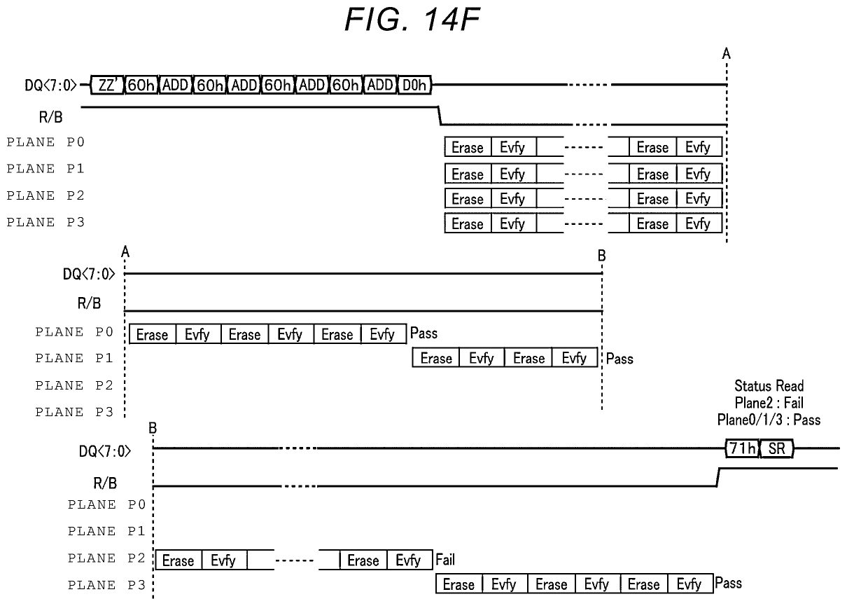

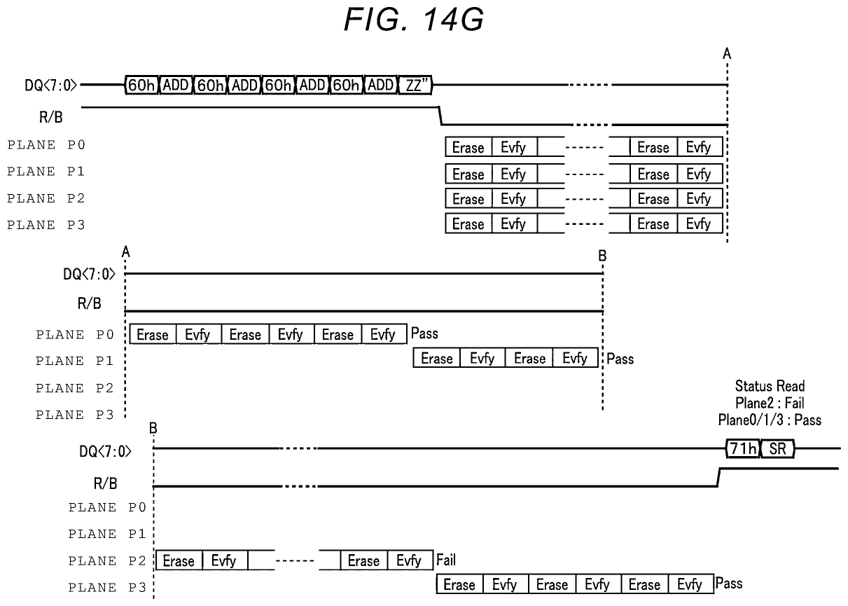

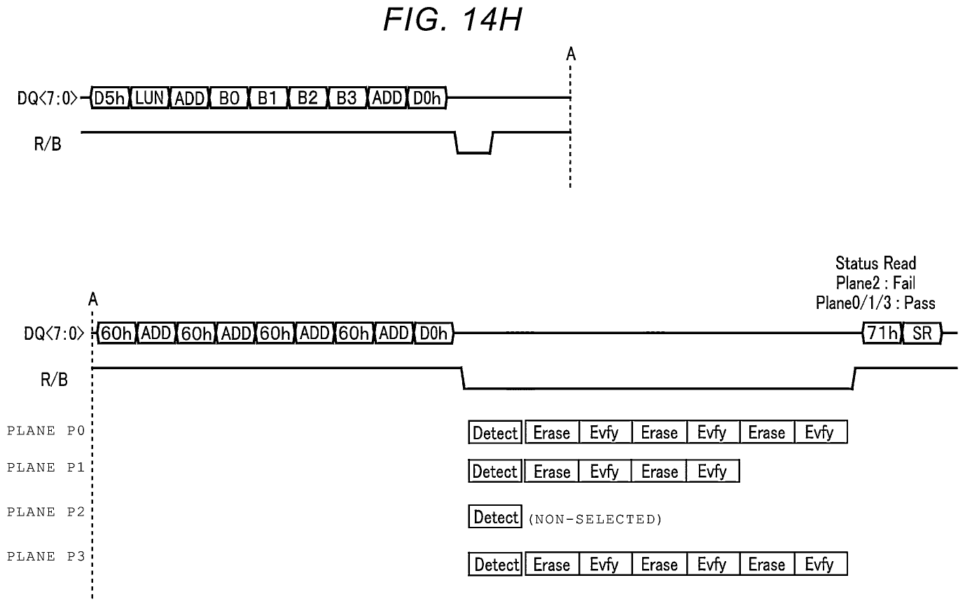

Next, a fourth embodiment will be described. The present embodiment differs from the above-described first to third embodiments in that when the memory controller 1 causes the non-volatile memory 2 to execute the erase operation, the timing at which the detection operation is performed can be specified and executed. Hereinafter, the erase operation in the present embodiment will be described using FIGS. 14A to 14H.

FIGS. 14A to 14H are diagrams illustrating an example of the command sequence and operation of each plane according to the fourth embodiment. In the erase operation in the present embodiment, a command specifying the timing of the detection operation is added before the command 60h transmitted as the signal DQ from the memory controller 1 to the non-volatile memory 2. The command to specify the timing of the detection operation is a prefixed command. In FIGS. 14A to 14F, a command XX, a command YY, a command YY′, a command ZZ, and a command ZZ′ are used as examples of prefixed commands.

When the command XX is added before the command 60h, the detection operation is performed before the first erase operation, as illustrated in FIG. 14A. When the command YY is added before the command 60h, the detection operation is performed following the first erase operation, as illustrated in FIG. 14B. When the command YY′ is added before the command 60h, the detection operation is performed during the first erase operation, as illustrated in FIG. 14C. When the command ZZ is added before the command 60h, the detection operation is performed after the ESF determination is made internally, as illustrated in FIG. 14D.

When a defective block is detected after the ESF determination and the erase operation is performed again with only a normal block, the detection operation may be performed without delay on the non-volatile memory 2 side after the ESF determination, as illustrated in FIG. 14D, or the command 71h and the command SR may be transmitted in order from the non-volatile memory 2 to the memory controller 1, and the command ZZ may be added again from the memory controller 1 side to instruct a re-erase, as illustrated in FIG. 14E.

When the command ZZ′ is added before the command 60h, after the ESF determination is made internally, the normal block BLK is selectively erased by selecting the planes P0 to P3 one by one and sequentially retrying the erase operation, as illustrated in FIG. 14F.

In addition to adding the prefixed command before the command 60h as described above, a method of replacing the execution command from the command D0h to the prefixed command and transmitting the replaced command can also be used to specify the timing of the detection operation. For example, as illustrated in FIG. 14G, by setting the execution command to the command ZZ″, after the ESF determination is made internally, the normal block BLK is selectively erased by selecting the planes P0 to P3 one by one and sequentially retrying the erase operation without the detection operation. That is, the erase operation illustrated in FIG. 14G is the same operation as the erase operation illustrated in FIG. 14F. As such, when instructing the timing of the detection operation or the re-erase operation after the ESF determination, a command sequence that grants the command ZZ′ before the command 60h may be transmitted, or a command sequence that replaces the execution command by the command ZZ″ may be transmitted.

The timing of the detection operation may be set in advance by a parameter setting change command (Set Feature command) prior to the erase operation. When setting the timing of the detection operation using the Set Feature command, a command sequence such as the sequence illustrated in FIG. 14H can be used, for example. That is, the settings can be switched as described above by transmitting a command D5h, that is a Set Feature command, a command LUN, and the address ADD, subsequently transmitting data B0 to B3, and finally transmitting the execution command D0h. Any of the bits of the data B0 to B3 is used to switch the setting of the detection execution timing. FIG. 14H illustrates the case where the timing of the detection operation is set before the first erase operation by the Set Feature command.

As such, the memory controller 1 can cause the non-volatile memory 2 to switch the timing of the detection operation by adding the prefix command at the head, by changing the execution command, or by the Set Feature command.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device, comprising:
a plurality of planes, each of the plurality of planes including at least one or more blocks, each of the one or more blocks including a plurality of memory cells,
a controller configured to erase data of each of the plurality of memory cells in an erase target block selected in each of the plurality of planes, by executing an erase sequence that repeats a plurality of loops, each of the loops including a set of an erase operation that erases the data of each of the plurality of memory cells in the erase target block and an erase verification operation that checks whether the data is erased, and
a source line electrically connected to one end of the plurality of memory cells in the plurality of planes,
for each of the plurality of the erase target blocks, the controller is configured to detect whether there is a current leak from the source line, determine validity of the erase sequence based on a detection result, and stop execution of the erase sequence for the erase target blocks that are determined not to be valid.

2. The semiconductor memory device according to claim 1, further comprising:
a first voltage generation circuit configured to generate a voltage to be supplied to the source line, wherein
the first voltage generation circuit is configured to supply an erase voltage to the source line during the erase operation.

3. The semiconductor memory device according to claim 2, further comprising:
a plurality of word lines connected to gates of the plurality of memory cells, respectively; and
a plurality of second voltage generation circuits configured to generate voltages to be supplied to the plurality of word lines, wherein
during the erase operation, the plurality of word lines in the erase target block in at least one of the planes are supplied with a ground voltage from the second voltage generation circuit corresponding to the at least one plane.

4. The semiconductor memory device according to claim 3, wherein
each of the plurality of planes further includes a first detection circuit configured to execute a first detection operation to detect a current of the plurality of word lines supplied with a voltage from the corresponding second voltage generation circuit,
each of the first detection circuits configured to perform the first detection operation while the erase voltage is supplied from the first voltage generation circuit to the source line and the ground voltage is supplied from the second voltage generation circuit to a plurality of the word lines connected to the plurality of memory cells in the erase target block, and
the controller configured to determine that the erase target block is not valid in the erase sequence when the current is detected in the first detection operation.

5. The semiconductor memory device according to claim 3, wherein
the first voltage generation circuit further includes a second detection circuit configured to execute a second detection operation that detects the number of clocks of a charge pump that generates a voltage of the source line,
the second detection circuit configured to perform the second detection operation while the erase voltage is supplied from the first voltage generation circuit to the source line and the ground voltage is supplied from one second voltage generation circuit to a plurality of the word lines connected to the plurality of memory cells in the erase target block, and
the controller configured to determine that the erase target block is not valid in the erase sequence when the number of clocks is higher than a set threshold in the second detection operation.

6. The semiconductor memory device according to claim 1, wherein
for each of the plurality of erase target blocks, the controller is configured to sequentially execute the erase operation and the erase verification operation, and in the erase verification operation, determine that the erase target blocks whose erase degree of the data is less than or equal to a set value are not valid in the erase sequence.

7. The semiconductor memory device according to claim 4, wherein
the controller is configured to make the determination after the first erase operation in the erase sequence is executed, and after the determination operation is completed, the erase sequence is executed from the erase verification operation.

8. The semiconductor memory device according to claim 4, wherein
the controller is configured to make the determination before the first erase operation in the erase sequence is executed, and after the determination operation is completed, the erase sequence is executed from the erase operation.

9. A data erasing method for a semiconductor memory device comprising a plurality of planes, wherein
each of the plurality of planes includes at least one or more blocks,
the block includes a plurality of memory cells,
a source line electrically connected to one end of the plurality of memory cells in the plurality of planes is provided,
the data erasing method includes:
detecting whether there is a current leak from the source line for each of the erase target blocks selected in each of the plurality of planes, and
determining, based on a detection result, validity of an erase sequence that repeats a plurality of loops including a set of an erase operation that erases data of each of the plurality of memory cells in each of the blocks and an erase verification operation that checks whether the data is erased, and
stopping execution of the erase sequence for the erase target blocks that are determined not to be valid.

10. The data erasing method according to claim 9, wherein
detecting whether there is a current leak from the source line further includes
measuring the number of operating clocks of a charge pump that supplies voltage to the source line for each of the selected blocks in each of the plurality of planes, between the first erase operation and the first erase verification operation of the erase sequence, and
determining that the erase sequence is not valid in the block where the number of operating clocks exceeds a set threshold.

11. A semiconductor memory device comprising a first plane and a second plane, wherein
the first plane includes a first block including a first memory cell,
the second plane includes a second block including a second memory cell,
the semiconductor memory device further comprises:
a source line electrically connected to one end of the first and second memory cells,
a second voltage generation circuit configured to supply voltage to the source line,
a second detection circuit configured to execute a second detection operation that detects the number of clocks of a charge pump that generates a voltage of the source line in the second voltage generation circuit, and
a controller configured to execute an erase sequence that repeats a plurality of loops including a set of an erase operation that erases data of the first memory cell and the second memory cell and an erase verification operation that checks whether the data is erased,
the second detection circuit configured to perform the second detection operation between the first erase operation and the first erase verification operation when the erase voltage is supplied to the source line from the first voltage generation circuit and the ground voltage is supplied to a plurality of word lines connected to either the first memory cell or the second memory cell, and
when the number of clocks detected in the second detection operation is higher than a threshold in the first plane and the number of clocks detected in the second detection operation is lower than a threshold in the second plane, the controller configured to stop execution of the erase sequence for the first plane and execute the erase sequence for the second plane.
